(19) United States
(12) Patent Application Publication
(10) Pub. No.: US 2011/0186874 A1
(43) Pub. Date: Aug. 4, 2011

(54) White Light Apparatus and Method

(75) Inventor: Frank Tin Chung Shum, Sunnyvale, CA (US)

(73) Assignee: Soraa, Inc., Fremont, CA (US)

(21) Appl. No.: 13/019,897

(22) Filed: Feb. 2, 2011

Related U.S. Application Data
(60) Provisional application No. 61/301,193, filed on Feb. 3, 2010.

(51) Int. Cl. H01L 33/52; H01L 33/60

(52) U.S. Cl. 257/88; 438/28; 257/E33.059; 257/E33.072

(57) ABSTRACT

A method of manufacturing LED devices using substrate scale processing includes providing a substrate member having a surface region. A reflective layer is disposed on the surface region, the reflective surface having a reflectivity of at least 85%, An array of conductive regions is spatially disposed on the reflective surface. LED devices are affixed to each of the array regions.

### CROSS-REFERENCE TO RELATED APPLICATION

This application claims priority to U.S. Provisional Patent Application No. 61/301,193, filed Feb. 3, 2011, commonly assigned and incorporated by reference hereby for all purposes.

### BACKGROUND OF THE INVENTION

This invention relates to lighting techniques. Embodiments of the invention include techniques for packaging an array of LED devices fabricated from bulk gallium and nitrogen containing materials with use of phosphors, or fabricated on other materials. The invention can be applied to white lighting, multi-colored lighting, general illumination, decorative lighting, automotive and aircraft lamps, street lights, lighting for plant growth, indicator lights, lighting for flat panel displays, and other optoelectronic devices.

In the late 1800's, Thomas Edison invented the light bulb. The conventional light bulb uses a tungsten filament enclosed in a glass bulb sealed in a base, which is screwed into a socket. The socket is coupled to a power source. Unfortunately, the conventional light bulb dissipates more than 90% of the energy used as thermal energy. Additionally, the conventional light bulb eventually fails due to evaporation of the tungsten filament.

Fluorescent lighting uses a tube structure filled with a noble gas and usually mercury. A pair of electrodes is coupled to an alternating power source through a ballast. When the mercury has been excited, it discharges emitting UV light. Phosphors, excited by the UV light, emit white light. Solid state lighting relies upon semiconductor materials to produce light emitting diodes (LEDs). Red LEDs use Aluminum Indium Gallium Phosphide or AlInGaP semiconductor materials. Shuji Nakamura pioneered the use of InGaN materials to produce LEDs emitting blue light LEDs. Blue LEDs led to innovations such as solid state white lighting, and other developments. Blue, violet, or ultraviolet-emitting devices based on InGaN are used in conjunction with phosphors to provide white LEDs.

### BRIEF SUMMARY OF THE INVENTION

This invention provides a method of manufacturing LED devices using substrate scale processing. The method includes providing a substrate having a surface and forming a reflective surface having a reflectivity of at least 85%. The method further includes forming a plurality of array regions spatially disposed on the reflective surface on which LED devices are formed. If desired, an electrical isolation layer is formed over the reflective layer, and a cover can be added over the LEDs. [0005]

In another embodiment, the invention provides a method for manufacturing a plurality of light chips, each having a plurality of LEDs. A silicon material has a polished surface region. A reflective material is formed over the surface region, and then electrical isolation material is formed over the reflective material. A plurality of array regions, each of the array regions having conductive contacts, are formed, and LEDs are placed on the conductive contacts. Encapsulating material then is added to surround the LEDs.

In another specific embodiment, an LED module includes a lead frame member and a substrate having a surface region, the substrate being coupled to the lead frame member. The substrate member includes a reflective layer having a first reflectivity level over the surface region. Additionally, the apparatus includes an electrical isolation layer over the reflective layer. The apparatus also includes array regions disposed on the isolation layer, the array regions being electrically coupled to one another. LEDs are positioned on the array regions. The array of LED device can be configured for a current density of at least 50 amps per square centimeter.

In another embodiment, the module includes wavelength regions having wavelength conversion materials configured for each of a first, second and third wavelength range, each configured to output a determined wavelength emission spectrum of electromagnetic radiation.

In another embodiment, an LED module includes a substrate with a surface region. A reflective surface overlies the surface region. Conductive patterns are formed on the reflective material, and LEDs are attached to the conductive patterns. A luminescent material, excited by the LED wavelength, provides a first color light. A cover member over LEDs is substantially transparent, and a second color. The combination of the first and second color produces a third color of light.

The present device and method provides for an improved lighting technique with improved efficiency. The method and resulting structure are easier to implement using conventional process technology. In a specific embodiment, a blue LED device emits electromagnetic radiation at a wavelength from about 440 nanometers to about 495 nanometers, a green LED emits electromagnetic radiation at a wavelength range from about 495 nanometers to about 590 nanometers, and a red LED emits electromagnetic radiation at a wavelength range from about 590 nanometers to about 660 nanometers. In a preferred embodiment, the present method and apparatus uses LED devices configured for violet (380 to 440 nm) electromagnetic radiation, as well as combinations. Depending on the application, more than more than three colors may be used to produce light of a desired color and quality.

### BRIEF DESCRIPTION OF THE DRAWINGS

FIG. 1A is a diagram illustrating a light emitting diode;

FIG. 1B is diagram illustrating a plan view of an LED apparatus;

FIG. 1C is a diagram illustrating an alternative light emitting diode apparatus;

FIG. 1D is diagram illustrating a plan view of an LED apparatus;

FIG. 1E is a diagram illustrating an alternative light emitting diode apparatus;

FIG. 2 is a diagram illustrating a process for manufacturing an LED package with LED devices arranged in array;

FIG. 3 is a diagram illustrating a process for manufacturing an LED package with LED devices arranged in array;

FIG. 4 is diagram illustrating an LED package;

FIG. 5 is diagram illustrating a 3-D view of an LED package;

FIG. 6 is a diagram illustrating mounting of LED package;

FIG. 7 is a diagram illustrating alternative mounting of LED package;

FIG. 7A is a diagram illustrating an alternative mounting of circular LED package;

FIG. 8 is a diagram illustrating an AC powered LED light;

FIG. 8A is a diagram of an exploded view of an AC powered LED light;

FIG. 8B is a diagram illustrating an LED light system;

FIG. 9 is a diagram illustrating assembling of an AC powered LED light;

FIG. 10 is a diagram illustrating heat dissipation of LED packages;

FIG. 11 is a diagram illustrating heat dissipation of an LED package attached to a heat sink;

FIG. 12 is a circuit diagram illustrating an LED array;

FIG. 12A is a diagram illustrating operation of an LED array;

FIG. 13 is a diagram illustrating performance of LED apparatus;

FIG. 14 is a circuit diagram illustrating an LED array with resistor tuning;

FIG. 15 is a circuit diagram illustrating an LED array with AC resistor;

FIG. 15A is a circuit diagram illustrating an LED array using 220V AC power source;

FIG. 15B is a circuit diagram illustrating an LED array configured to using a 24V DC power source;

FIG. 16 is a diagram illustrating color tuning for LED devices;

FIG. 17 is a diagram illustrating color tuning using color filter for LED devices;

FIG. 18 is a diagram illustrating color tuning using a luminescent plate for LED devices;

FIG. 19 is a diagram illustrating color tuning using absorbing and/or reflective material for LED devices; and

FIG. 20 is a diagram illustrating color tuning using LED devices with different colors.

### DETAILED DESCRIPTION OF THE INVENTION

Herein “LED device” refers to a light emitting diode and “LED package” refers to packaged LED device with optional associated electrical components such as resistors, diodes, and capacitors. Conventional LED devices suffer from multiple disadvantages. For example, to achieve high light output, LED devices are often bundled together. This arrangement is costly and results in a large structure.

To favorably compete in the lighting market, it is desirable to lower the cost of generating light from LEDs. This can be achieved by increasing the output—lumens per unit area—requiring that device operating current densities increase. Typical operating current densities for commercially available LEDs are <100 A/cm². Laser diodes based on GaN demonstrate operating current densities of 5-10 kA/cm², an increase of up to 100×. Thus, there is a capability for increased operating current density for LEDs, thereby reducing the cost of light generation and increasing penetration of LED-based solutions into the general lighting market. Today's commercially available LEDs, however, are manufactured on substrates such as sapphire, SiC, or silicon. This results in a high density of dislocations which are known to reduce the lifetimes of GaN-based optoelectronic devices at high current densities. This effect is particular pronounced in laser diodes. Furthermore, typical InGaN-based LEDs exhibit a reduction in efficiency with increasing current density (“current droop”). Improvements against current droop have been demonstrated in InGaN-based LEDs fabricated from bulk GaN substrates. Also, the low dislocation densities (<˜1E7 cm-2) offered by bulk GaN substrates could offer reliable operation at high current densities. What is needed is an LED device which can leverage the advantages of bulk GaN, while providing the necessary operating characteristics useful for lighting, i.e., high lumen density, good thermal management, high conversion efficiency to white light, high reliability, and a flexible power interface.

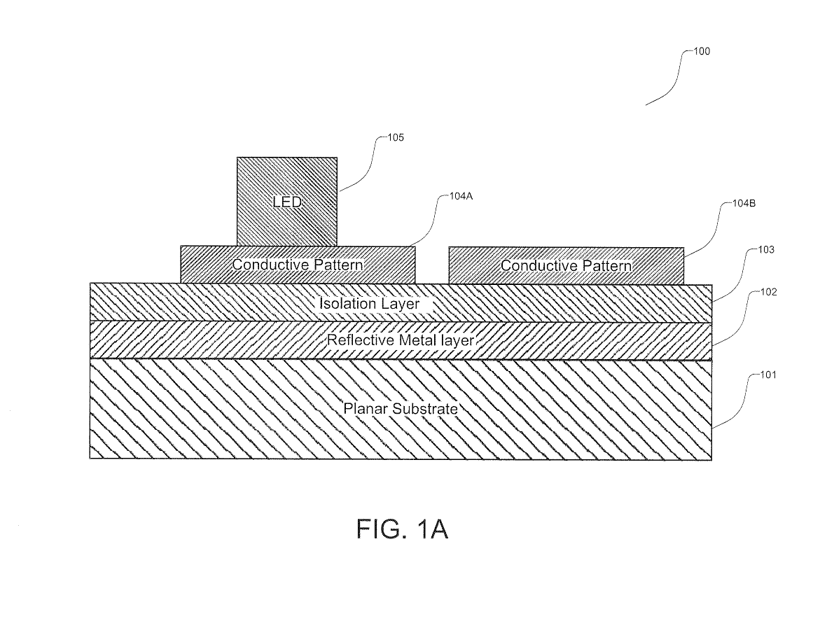

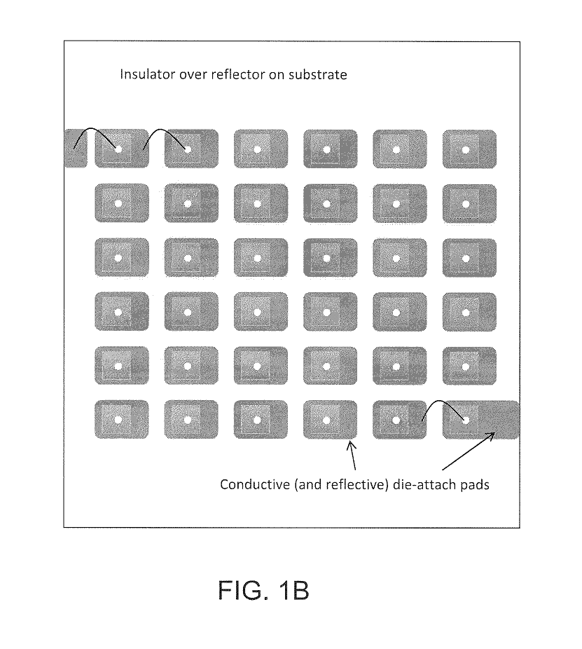

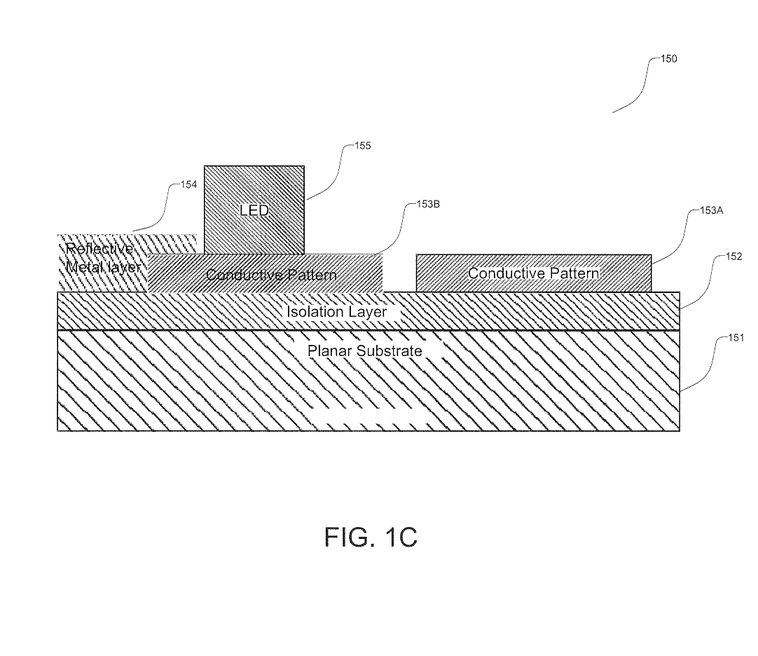

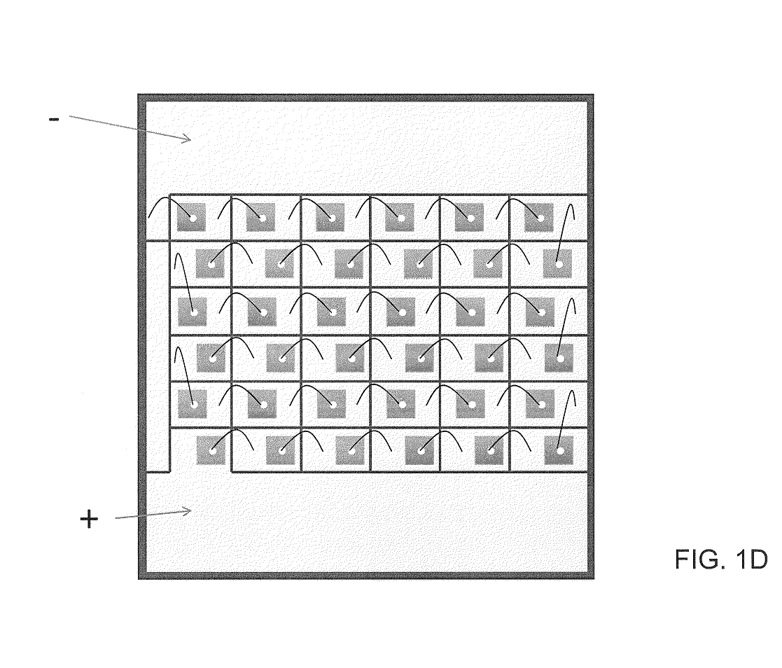

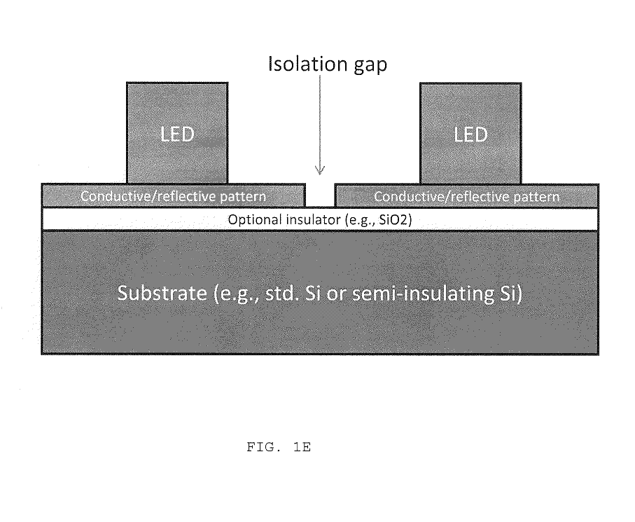

FIG. 1A is a diagram of a light emitting diode apparatus. LED package 100 includes a substrate 101, a reflective layer 102, an isolation layer 103 that is electrically isolating, conductive patterns 104A and 104B, and LED 105. The substrate 101 is silicon material having a substantially flat surface region, preferably achieved by a polishing process. The substrate 101 can also be silicon, metal, ceramic, glass, or a single crystal wafer. The reflective layer 102 causes the light emitted by the LED 105 and any luminescent material to be reflected by, as opposed to being absorbed by, the substrate 101. The reflective layer 102 has reflectivity of at least 80%, and typically reflectivity greater than 92%.

The reflective layer 102 may be made from various materials, for example, silver or aluminum. In one embodiment, a dielectric coating is added to the silver or aluminum layer to enhance reflectivity. The reflector 102 typically has average reflectivity greater than 90%, 95%, 98%, and sometimes greater than 99%, at wavelengths between about 390 nanometers and about 800 nanometers. In one embodiment, the reflective layer comprises multiple layers of metal materials and dielectric layers.

An electrical and optically transparent isolation layer 103 is provided between the reflective layer 102 and the conductive patterns 104A and 104B. The isolation layer 103 consists of dielectric material that provides electrical insulation between the reflective layer 102 and the conductive patterns 104. The dielectric coating sometimes enhances the reflectivity of the metal layer, yet provides the electrical insulation function.

The isolation layer 103 is usually dielectric material. In various embodiments, SiO₂, AlN, Al₂O₃, and/or SiN or combinations thereof may be used. In one embodiment, the isolation layer is greater than 1 micron in thickness and provides greater than 1 kilovolt of electrical isolation between the reflector and the 102 and the conductive pattern 104. Used for electrical insulation, the isolation layer preferably has a thermal conductivity of at least 1 W(m-K).

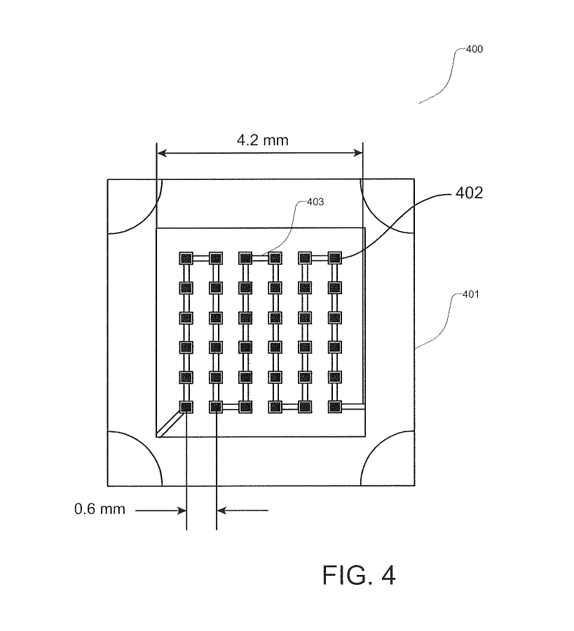

Conductive patterns 104A and 104B, usually silver or aluminum, are on top of the isolation layer 103. In the FIG. 1 side view, only two conductive patterns are shown, but the LED package may have a large number of conductive patterns arranged in an array, e.g. an M by N array of conductive patterns as shown in FIG. 4. Each of the conductive patterns is used to power an LED device, and can include additional circuitry for that purpose. During the manufacturing process, the conductive patterns are electrically isolated from each other when first formed on the isolation later, then later connected to one another (e.g., by wire bonding) in a desired configuration. The wire bonding process may be performed before or after deposition of phosphor material. The conductive patters are preferably reflective, for example having reflectivity of at least 80%.

The LED devices provided on the conductive patterns can be arranged in a configuration with particular LEDs of specific wavelength disposed in a desired pattern. In the figure, LED 105 is connected to the conductive pattern 104A, which includes a circuit for providing power to LED 105. The LED package 100, depending on the application, may include other components. Usually, the LED devices and the wire bonds and other circuits are encapsulated, for example, in silicone, sometimes with phosphors. The apparatus 100 also can include a cover member on top of the LEDs to protect them and/or to adjust the color of light emitted from the LED package.

The LED package may be powered in various ways, for example, by including a DC or an AC power interface. The LED package can include an active driver circuit or a full-wave rectifier circuit to power the LEDs. The LED devices can be connected in series configuration or series-parallel configuration to achieve a forward voltage to match the power supply. LED package 100, constructed with an array of LED devices, can be flexibly implemented. The amount of light output from the LED package can be adjusted by change the number of LED devices or by reducing the dimensions of the LED chips.

FIG. 1B is diagram illustrating a plan view of an LED apparatus. As shown, LED devices are provided on conductive pads. To power an LED device, the top portion of an LED device is connected to one electrical junction, and the bottom portion of the LED device is connected to another electrical junction through the conductive pad directly below.

FIG. 1C is a diagram illustrating an alternative light emitting diode apparatus according to an embodiment of the invention. As shown an LED package 150 includes a substrate 151, a optional reflective layer 154, an isolation layer 152, conductive patterns 153A and 153B, and LED 155. The substrate 151 is a planar substrate having a substantially flat surface region. The planar surface can be obtained by polishing, and preferably consists essentially of silicon, but may be metal, ceramic, glass, a crystalline wafer, or the like. An optional electrically dielectric isolation layer(s) 152 is provided over the substrate 155. The isolation layer 152 provides electrical insulation between the substrate 151 and the conductive patterns 153. The isolation layer may be formed of materials and in the manner described with regard to FIG. 1A.

FIG. 1C differs from FIG. 1A in having a reflective layer 154 on top of the conductive pattern 153B and isolation layer 152. Reflective layer 154 reflects light emitted by the LED 105 and/or the luminescent material. Preferably, reflective layer 154 has a high degree of reflectivity of at least 80%, but in one embodiment, the average reflectivity of the reflective layer is greater than 97%.

The reflective layer 154 may be made from various types of materials such as silver or aluminum. A dielectric coating can be added to the silver or aluminum layer to further enhance reflectivity. Such a reflector 154 can have a average reflectivity greater than 90%, 95%, 98%, or even greater than 99%, at wavelengths between about 390 nanometers and about 800 nanometers. In one embodiment, the reflective layer comprises multiple layers, including a metal reflective layer and a dielectric layer. As described above, the LED package 150 may include other components such as wire bonds, encapsulating material, and a cover, and can be powered appropriately. Beneath the metal reflector is a electrical isolation layer not shown in FIG. 1C that electrically isolates the metal reflector layer from the circuit layer. In another embodiment, the reflective alyer 154 is not metal but a high reflective diffuse reflector such as anatases of rutile TiO2 particles.

FIG. 1D is diagram illustrating a plan view of an LED apparatus illustrating the wire bonds. To power an LED device, the top portion of an LED device is connected to one electrical junction, and the bottom portion of the LED device is connected to another electrical junction through the conductive pad below.

FIG. 1E is a diagram illustrating an alternative light emitting diode apparatus according to another embodiment of the present invention. The structure depicted is similar to those described above. In FIG. 1E, however, the substrate material may be conductive or semi-insulating. If substrate material is conductive (e.g., resistivity of less than 100 ohms-cm), an isolation layer is provided between the conductive patterns and the substrate material. On the other the hand, if the substrate material is semi-insulating (e.g., resistivity of at least 100 ohms-cm), the isolation layer is optional, and the conductive patterns may be provided directly on the substrate material if the substrate material. The conductive patterns are electrically isolated from each other by an isolation gap, which can be an air gap or filled with insulating material.

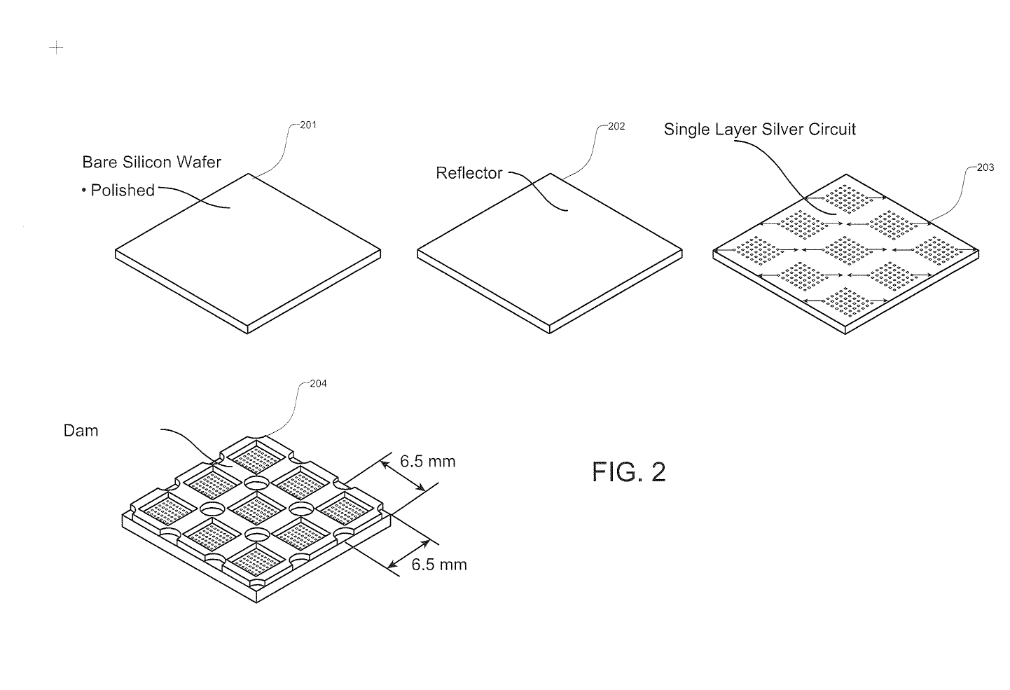

FIG. 2 is a diagram illustrating a process for manufacturing an LED package with LED devices arranged in array. A silicon wafer substrate 201 is used as substrate material for manufacturing the LED package. Here an 8″ wafer is selected for its relatively low costs (about $65 per wafer in early 2010). Wafers in other sizes may be used both for efficiency and economy.

The silicon substrate 201 is polished and has a plain surface. The silicon substrate 201 has high thermal conductivity, for example, a bulk thermal conductivity greater than 50 W/(m-k) After the silicon substrate 201 is processed, a reflective surface is formed on its surface. In FIG. 2, the substrate 202 includes a silicon substrate 201 with a reflective layer, e.g. silver, aluminum or other coating, on top of the substrate.

An optically transparent electrical isolation layer 103, usually about 0.5 microns thick is formed over the reflective layer. This layer was described above with regard to FIG. 1. A layer of conductive patterns are formed on substrate 203. As shown on substrate 203, nine sets of conductive patterns are formed in a configuration of 3×3, each set of conductive pattern composing of 36 conductive regions for mounting of LED devices. The conductive patterns is formed using a desired foundry compatible process. In one embodiment all the electrical contacts and conductive pattern are on the single top surface of the silicon, thus no expensive vias are necessary. The material and processes used for forming the conductive patterns are selected for both low costs and high performance (e.g., about $25 per wafer in early 2010). The conductive pattern includes metal material for providing electrical contacts, and also is highly reflective.

A dam structure, for example of silicone, is formed to separate conductive patterns from one another, as shown on substrate 204. Each of the conductive patterns enclosed by the silicon dam has a dimension of about 6.5 mm×6.5 mm. The dam also can be made from any suitable material, e.g. plastic, silicon, metal, ceramics, Teflon, etc. The cavity structure of the dam retains liquid silicone material. In a preferred embodiment, the dam is optically reflective with a specular or diffuse reflectivity greater than 50%.

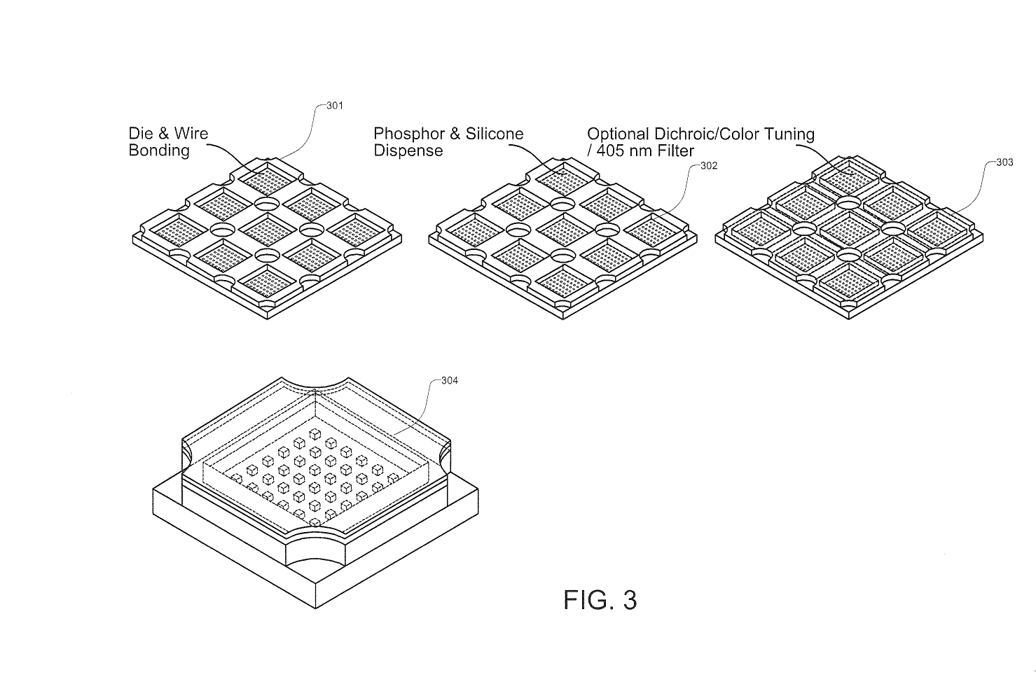

FIG. 3 is a diagram illustrating a process for manufacturing an LED package with LED devices arranged in array. FIG. 3 illustrates partially manufactured LED package as shown in FIG. 2. On the substrate 301, die and wire bonding are formed to connect circuits of the conductive patterns. Depending on the application, various types of wire bonding processes may be used, such as ball bonding, wedge bonding, and others. Various types of materials may be used for providing wire bonds, for example, gold, silver, copper, aluminum, and/or other material are used. The wire bonding process may be performed before or after forming the dams.

On the substrate 301, LED devices are bonded to the conductive patterns. Each of the LED devices is usually less than about 300 micrometers by about 300 micrometers. Of course, any desired types of LED device may be used, such as LEDs emitting ultraviolet, violet, and/or blue color, formed using bulk Galium Nitride (GaN) material. Preferably the LED devices are high-performance single-color polar, non-polar, and/or semi-polar LEDs, which interact with wavelength conversion material(s) to provide white light. The LED die can be bonded on to the conductive pattern using a solder material such as gold tin solder or silver die-attach epoxy.

In one embodiment, a violet non-polar or semi-polar or polar LED is packaged together with a blend of three phosphors, emitting in the blue, the green, and the red. In another embodiment, a blue non-polar or semi-polar or polar LED is packaged together with a blend of two phosphors, emitting in the green and the red. In still another embodiment, a green or yellow polar, non-polar, or semi-polar LED is packaged together with a blue LED and phosphor which emits in the red. Various types of phosphor materials may be used, e.g. as described in U.S. Patent Application No. 61/301,183, filed Feb. 3, 2010 (Attorney Docket No. 027364-009900), titled “Reflection Mode Package for Optical Devices Using Gallium and Nitrogen Bearing Materials,” which is incorporated by reference herein for all purposes.

A non-polar or semi-polar or polar LED may be fabricated on a bulk gallium nitride substrate. The gallium nitride substrate may be sliced from a boule that was grown by hydride vapor phase epitaxy or ammonothermally, according to methods known in the art. In one specific embodiment, the gallium nitride substrate is fabricated by a combination of hydride vapor phase epitaxy and ammonothermal growth, as disclosed in U.S. Patent Application No. 61/078,704, commonly assigned, and hereby incorporated by reference herein. The boule may be grown in the c-direction, the m-direction, the a-direction, or in a semi-polar direction on a single-crystal seed crystal. Semipolar planes may be designated by (hkil) Miller indices, where i=−(h+k), l is nonzero and at least one of h and k are nonzero. The gallium nitride substrate may be cut, lapped, polished, and chemical-mechanically polished. The gallium nitride substrate orientation may be within ±5 degrees, ±2 degrees, ±1 degree, or ±0.5 degrees of the {1 −1 0 0} m plane, the {1 1 −2 0} a plane, the {1 1 −2 2} plane, the {2 0 −2 ±1} plane, the {1 −1 0 ±1} plane, the {1 −1 0−±2} plane, or the {1 −1 0 ±3} plane. The gallium nitride substrate may have a dislocation density in the plane of the large-area surface that is less than 10⁸ cm⁻², less than 10⁷ cm⁻², less than 10⁶ cm⁻², less than 10⁵ cm⁻², less than 10⁴ cm², or less than 10³ cm⁻². The gallium nitride substrate may have a dislocation density in the c plane that is less than 10⁸ cm⁻², 10⁷ cm⁻², 10⁶ cm⁻², 10⁵ cm⁻², 10⁴ cm⁻², or even less than 10³ cm⁻².

A homoepitaxial non-polar or semi-polar LED is fabricated on the gallium nitride substrate according to methods that are known in the art, for example, following the methods disclosed in U.S. Pat. No. 7,053,413, which is hereby incorporated by reference in its entirety. At least one AlₓIn_{y}Ga_{1-x-y}N layer, where 0≦x≦1, 0≦y≦1, and 0≦x+y≦1, is deposited on the substrate, for example, following the methods disclosed by U.S. Pat. Nos. 7,338,828 and 7,220,324, which are hereby incorporated by reference in their entirety. The at least one AlₓIn_{y}Ga_{1-x-y}N layer may be deposited by metal-organic chemical vapor deposition, by molecular beam epitaxy, by hydride vapor phase epitaxy, or by a combination thereof. In one embodiment, the AlₓIn_{y}Ga_{1-x-y}N layer comprises an active layer that preferentially emits light when an electrical current is passed through it. In one specific embodiment, the active layer comprises a single quantum well, with a thickness between about 0.5 nm and about 40 nm. In a specific embodiment, the active layer comprises a single quantum well with a thickness between about 1 nm and about 5 nm. In other embodiments, the active layer comprises a single quantum well with a thickness between about 5 nm and about 10 nm, between about 10 nm and about 15 nm, between about 15 nm and about 20 nm, between about 20 nm and about 25 nm, between about 25 nm and about 30 nm, between about 30 nm and about 35 nm, or between about 35 nm and about 40 nm. In another set of embodiments, the active layer comprises multiple quantum wells. In still another embodiment, the active region comprises a double heterostructure, with a thickness between about 40 nm and about 500 nm. In one specific embodiment, the active layer comprises an In_{y}Ga_{1-y}N layer, where 0≦y≦1.

Indium tin oxide (ITO) is e-beam evaporated onto the p-type contact layer as the p-type contact and rapid-thermal-annealed. LED mesas, with a size of about 300×300 μm², are formed by photolithography and dry etching using a chlorine-based inductively-coupled plasma (ICP) technique. Ti/Al/Ni/Au is e-beam evaporated onto the exposed n-GaN layer to form the n-type contact, Ti/Au is e-beam evaporated onto a portion of the ITO layer to form a p-contact pad, and the wafer is diced into discrete LED dies. Electrical contacts are formed by conventional wire bonding. Of course, there can be other variations, modifications, and alternatives. For example, p-down configurations are used, which is important for reflective p contacts based on Ag or Al.

In one embodiment of the device fabrication, a p-contact is deposited on the epitaxial structure. This layer can be comprised of Pt, Ag, Al, or any other suitable material, and can be patterned by metal liftoff or etch techniques. Subsequently, a diffusion barrier, such as TiW, is deposited on the p-contact. The wafer is then patterned and the epitaxial layers are etched past the active region to expose the n-type or bulk material. This GaN etch is usually accomplished via either plasma dry etching, but could be done, for example, with a photoelectrochemical etch. The mesa sidewalls are then passivated by a deposition and patterning of a dielectric layer, such as SiNx or SiO2. Subsequently, pad metal is deposited and patterned on top of the p-contact, through vias in the dielectric. This pad metal may be terminated in, for example, Au, AuSn, Cu, Ag, or Al, and enables subsequent attachment of the die to a carrier substrate. The wafer is then flipped over, and an n-contact is deposited and patterned. Prior to n-contact patterning, the bulk substrate may be thinned via, for example, diamond lapping. Finally, the wafer is singulated into individual dice using, for example, laser scribe and break, or diamond-blade sawing. Alternative flows could be constructed in which the mesa etch is done prior to the p-contact metallization. Similarly, the n-contact could be done as the first step, or partial singulation could precede the re-contact step. To enhance light extraction, a surface roughening step could also be applied, or the n-contact side or die sidewalls could be further patterned with extraction enhancing features. To facilitate heat removal from the LED chips, the devices are typically mounted p-side down to decrease the distance from the light generation region to the heat sink.

In a specific embodiment, the one or more entities comprise a blend of wavelength conversion materials capable of emitting blue light, green light, and red light. As an example, the blue emitting wavelength conversion material is selected from the group consisting of (Ba,Sr,Ca)₅(PO₄)₃(Cl,F,Br,OH):Eu²⁺, Mn²⁺; Sb³⁺, (Ba,Sr,Ca)MgAl₁₀O₁₇:Eu²⁺, Mn²⁺; (Ba,Sr,Ca)BPO₅:Eu²⁺, Mn²⁺; (Sr,Ca)₁₀(PO₄)₆*nB₂O₃:Eu²⁺; 2SrO*0.84P₂O₅*0.16B₂O₃:Eu²⁺; Sr₂Si₃O₈*2SrCl₂:Eu²⁺; (Ba,Sr,Ca)MgₓP₂O₇:Eu²⁺, Mn²⁺; Sr₄Al₁₄O₂₅:Eu²⁺ (SAE); BaAl₈O₁₃:Eu²⁺; and mixtures thereof. The green wavelength conversion material is selected from the group consisting of (Ba,Sr,Ca)MgAl₁₀O₁₇:Eu²⁺, Mn²⁺ (BAMn); (Ba,Sr,Ca)Al₂O₄:Eu²⁺; (Y,Gd,Lu,Sc,La)BO₃:Ce³⁺, Tb³⁺; Ca₈Mg(SiO₄)₄Cl₂:Eu²⁺, Mn²⁺; (Ba,Sr,Ca)₂SiO₄:Eu²⁺; (Ba,Sr,Ca)₂(Mg,Zn)Si₂O₇:Eu²⁺; (Sr,Ca,Ba)(Al,Ga,ln)₂S₄:Eu²⁺; (Y,Gd,Tb,La,Sm,Pr,Lu)₃(Al,Ga)₅O₁₂:Ce³⁺; (Ca,Sr)₈(Mg,Zn)(SiO₄)₄C₁₂:Eu²⁺, Mn²⁺ (CASI); Na₂Gd₂B₂O₇:Ce³⁺, Tb³⁺; (Ba,Sr)₂(Ca,Mg,Zn)B₂O₆:K,Ce,Tb; and mixtures thereof. The red wavelength conversion material is selected from the group consisting of (Gd,Y,Lu,La)₂O₃:Eu³⁺, Bi³⁺; (Gd,Y,Lu,La)₂O₂S:Eu³⁺, Bi³⁺; (Gd,Y,Lu,La)VO₄:Eu³⁺, Bi³⁺; Y₂(O,S)₃:Eu³⁺; Ca₁₋ₓMo_{1-y}Si_{Y}O₄, where 0.05≦x≦0.5, 0≦y≦0.1; (Li,Na,K)₅Eu(W,Mo)O₄; (Ca,Sr)S:Eu²⁺; SrY₂S₄:Eu²⁺; CaLa₂S₄:Ce³⁺; (Ca,Sr)S:Eu²⁺; 3.5MgO*0.5MgF₂*GeO₂:Mn⁴⁺ (MFG); (Ba,Sr,Ca)MgₓP₂O₇:Eu²⁺, Mn²⁺; (Y,Lu)₂WO₆:Eu³⁺, Mo⁶⁺; (Ba,Sr,Ca)₃MgₓSi₂O₈:Eu²⁺, Mn²⁺, wherein 1<x≦2; (RE_{1-y}Ce_{y})Mg₂₋ₓLiₓSi₃₋ₓPₓO₁₂, where RE is at least one of Sc, Lu, Gd, Y, and Tb, 0.0001<x<0.1 and 0.001<y<0.1; (Y, Gd, Lu, La)₂₋ₓEuₓW_{1-y}Mo_{Y}O₆, where 0.5≦x.≦1.0, 0.01≦y≦1.0; (SrCa)₁₋ₓEuₓSi₅N₈, where 0.01≦x≦0.3; SrZnO₂:Sm⁺³; MₘOₙX, wherein M is selected from the group of Sc, Y, a lanthanide, an alkali earth metal and mixtures thereof; X is a halogen; 1≦m≦3; and 1≦n≦4, and wherein the lanthanide doping level can range from 0.1 to 40% spectral weight; and Eu³⁺ activated phosphate or borate phosphors; and mixtures thereof.

Referring to FIG. 3, phosphor and silicone material are dispensed over the LED devices and wires, on device 302. Among other features, the silicone material acts as a medium fill that protects the LED devices and the wires. Additionally, the silicone material provides insulation and sealing for the electrical contacts and wires. Other types materials can be used for medium fill. For example, medium fill material includes epoxy, glass, spin on glass, plastic, polymer, which is doped, metal, or semiconductor material, including layered materials, and/or composites, and others. As stated above, the sequence of wire bonding and phosphor dispensing may be modified. In certain embodiments, phosphor dispense is performed before wire bonding.

Depending upon the embodiment, the medium including polymers begins as a fluidic state, which fills an interior region of the enclosure. In a specific embodiment, the medium fills and can seal the LED device or devices. The medium is then cured and fills in a substantially stable state according to a specific embodiment. The medium is preferably optically transparent or can also be selectively transparent and/or translucent according to a specific embodiment. In addition, the medium, once cured, is substantially inert according to a specific embodiment. In a preferred embodiment, the medium has a low absorption capability to allow a substantial portion of the electromagnetic radiation generated by the LED device to traverse through the medium and be outputted through the enclosure at one or more second wavelengths.

In other embodiments, the medium can be doped or treated to selectively filter, disperse, or influence one or more selected wavelengths of light. As an example, the medium can be treated with metals, metal oxides, dielectrics, or semiconductor materials, and/or combinations of these materials, and the like.

As an example, phosphor material is used as a part of wavelength conversion entities. In one embodiment, various types of material form wavelength conversion entities. In a preferred embodiment, wavelength conversion entities are provided by materials that convert electromagnetic radiation absorbed by the wavelength selective material, as shown. In a specific embodiment, the wavelength conversion entities are excited by the primary LED emission and emit electromagnetic radiation of second wavelength. Preferably, the entities emit substantially yellow light from an interaction with the blue light emission. In a specific embodiment, the mean dimension of the plurality of entities, which are phosphor grains, is about fifteen microns and less.

In one embodiment, phosphor particles are deposited onto the LED package. Phosphor particles may comprise any of the wavelength conversion materials listed above, or other materials known in the art. Phosphor particles 103 may have a mean-grain-diameter particle size distribution between about 0.1 micron and about 50 microns. In some embodiments, the particle size distribution of phosphor particles is monomodal, with a peak at an effective diameter between about 0.5 microns and about 40 microns. In other embodiments, the particle size distribution of phosphor particles is bimodal, with local peaks at two diameters, trimodal, with local peaks at three diameters, or multimodal, with local peaks at four or more effective diameters.

In a specific embodiment, the entities comprises a phosphor or phosphor blend selected from (Y,Gd,Tb,Sc,Lu,La)₃(Al,Ga,In)₅O₁₂:Ce³⁺, SrGa₂S₄:Eu²⁺, SrS:Eu²⁺, and colloidal quantum dot thin films comprising CdTe, ZnS, ZnSe, ZnTe, CdSe, or CdTe. In other embodiments, the device may include a phosphor capable of emitting substantially red light.

Quantum dot materials comprise a family of semiconductor and rare earth doped oxide nanocrystals whose size and chemistry determine their luminescent characteristics. Typical chemistries for the semiconductor quantum dots include well known (ZnxCd1−x) Se [x=0 . . . 1], (Znx,Cd1−x)Se [x=0 . . . 1], Al(AsxP1−x) [x=0 . . . 1], (Znx,Cd1−x)Te [x=0 . . . 1], Ti(AsxP1−x) [x=0 . . . 1], In(AsxP1−x) [x=0 . . . 1], (AlₓGa1−x)Sb [x=0.1], (Hgx,Cd1−x)Te [x=0 . . . 1] zinc blende semiconductor crystal structures. Published examples of rare-earth doped oxide nanocrystals include Y2O3:Sm3+, (Y,Gd)2O3:Eu3+, Y2O3:Bi, Y2O3:Tb, Gd2SiO5:Ce, Y2SiO5:Ce, Lu2SiO5:Ce, Y3Al5)12:Ce but should not exclude other simple oxides or orthosilicates. Many of these materials are being actively investigated as suitable replacement for the Cd and Te containing materials which are considered toxic.

Such phosphor is selected from one or more of (Gd,Y,Lu,La)₂O₃:Eu³⁺, Bi³⁺; (Gd,Y,Lu,La)₂O₂S:Eu³⁺, Bi³⁺; (Gd,Y,Lu,La)VO₄:Eu³⁺, Bi³⁺; Y₂(O,S)₃:Eu³⁺; Ca₁₋ₓMo_{1-y}Si_{y}O₄, where 0.05≦x≦0.5, 0≦y≦0.1; (Li,Na,K)₅Eu(W,Mo)O₄; (Ca,Sr)S:Eu²⁺; SrY₂S₄:Eu²⁺; CaLa₂S₄:Ce³⁺; (Ca,Sr)S:Eu²⁺; 3.5MgO*0.5MgF₂*GeO₂:Mn⁴⁺ (MFG); (Ba,Sr,Ca)MgxP₂O₇:Eu²⁺, Mn²⁺; (Y,Lu)₂WO₆:Eu³⁺, Mo⁶⁺; (Ba,Sr,Ca)₃MgxSi₂O₈:Eu²⁺, Mn²⁺, wherein 1<x≦2; (RE_{1-y}Ce_{y})Mg₂₋ₓLiₓSi₃₋ₓPₓO₁₂, where RE is at least one of Sc, Lu, Gd, Y, and Tb, 0.0001<x<0.1 and 0.001<y<0.1; (Y, Gd, Lu, La)₂₋ₓEuₓW_{1-y}Mo_{Y}O₆, where 0.5≦x.≦1.0, 0.01≦y≦1.0; (SrCa)₁₋ₓEuₓSi₅N₈, where 0.01≦x≦0.3; SrZnO₂:Sm⁺³; MₘOₙX wherein M is selected from the group of Sc, Y, a lanthanide, an alkali earth metal and mixtures thereof; X is a halogen; 1≦m≦3; and 1≦n≦4, and wherein the lanthanide doping level can range from 0.1 to 40% spectral weight; and Eu³⁺ activated phosphate or borate phosphors; and mixtures thereof.

The wavelength conversion materials can be ceramic, thin-film-deposited, or discrete particle phosphors, ceramic or single-crystal semiconductor plate down-conversion materials, organic or inorganic down-converters, nanoparticles, or any other materials which absorb one or more photons of a primary energy and thereby emit one or more photons of a secondary energy (“wavelength conversion”). As an example, the wavelength conversion materials include the following:

(Sr,Ca)₁₀(PO₄)6*DB₂O₃:Eu²⁺ (wherein 0<n₁)

(Ba,Sr,Ca)₅(PO₄)₃(Cl,F,Br,OH):Eu²⁺,Mn²⁺

(Ba,Sr,Ca)BPO₅:Eu²⁺,Mn²⁺

Sr₂Si₃O₈*2SrC₁₂:Eu²⁺

(Ca,Sr,Ba)₃MgSi₂O₈:Eu²⁺,Mn²⁺

BaA₁₈O₁₃:Eu²⁺

₂SrO*0.84P₂O₅*0.16B₂O₃:EU²⁺

(Ba,Sr,Ca)MgAl₁0O₁₇:Eu²⁺,Mn²⁺

(Ba,Sr,Ca)Al₂O₄:Eu²⁺

(Y,Gd,Lu,Sc,La)BO₃:Ce³⁺,Tb³⁺

(Ba,Sr,Ca)₂(Mg,Zn)Si₂O₇:Eu²⁺

(Mg,Ca,Sr,Ba,Zn)₂Si₁_{_{—}}ₓO₄_{_{—}}₂x:Eu²⁺ (wherein 0<x=0.2)

(Sr,Ca,Ba)(Al,Ga,m)₂S₄:Eu²⁺

(Lu,Sc,Y,Tb)₂_{_{—}}ᵤ_{_{—}}ᵥCevCa₁₊ᵤLiwMg₂_{_{—}}_{w}Pw(Si,Ge)₃_{_{—}}_{w}01₂_{_{—}}ᵤ/2 where —O.SSû1; 0<v£Q.1; and OSŵO.2

(Ca,Sr)₈(Mg,Zn)(SiO₄)₄C₁₂:Eu²⁺,Mn²⁺

Na₂Gd₂B₂O₇:Ce³⁺,Tb³⁺

(Sr,Ca,Ba,Mg,Zn)₂P₂O₇:Eu²⁺,Mn²⁺

(Gd,Y,Lu,La)₂O₃:Eu³⁺,Bi³⁺

(Gd,Y,Lu,La)₂O₂S:Eu³⁺,Bi³⁺

(Gd,Y,Lu,La)_{V}O₄:Eu³⁺,Bi³⁺

(Ca,Sr)S:Eu²⁺,Ce³⁺

(Y,Gd,Tb,La,Sm,Pr,Lu)₃(Sc,Al,Ga)₅_{_{—}}ₙO₁₂_{_{—}}₃/₂n:Ce³⁺ (wherein 0̂0̂0.5)

ZnS:Cu+,Cl˜

ZnS:Cu+,Al³⁺

ZnS:Ag+,Al³⁺

SrY₂S₄:EU²⁺

CaLa₂S₄:Ce³⁺

(Ba,Sr,Ca)MgP₂O₇:Eu2+,Mn²⁺

(Y,Lu)₂WO₆:Eu³⁺,Mo⁶⁺

(Ba,Sr,Ca)nSinNn:Eu²⁺ (wherein 2ₙ₊₄=3n)

Ca₃(SiO₄)Cl₂:Eu²⁺

ZnS:Ag+,Cl˜

(Y,Lu,Gd)₂_{_{—}}ₙCanSi₄N₆₊ₙC₁_{_{—}}ₙ:Ce³+, (wherein OSn̂O.5)

(Lu,Ca,Li,Mg,Y)alpha-SiAlON doped with Eu²⁺ and/or Ce³⁺

(Ca,Sr,Ba)SiO₂N₂:Eu²⁺,Ce³⁺

For purposes of the application, it is understood that when a phosphor has two or more dopant ions (i.e., those ions following the colon in the above phosphors), this is to mean that the phosphor has at least one (but not necessarily all) of those dopant ions within the material. That is, as understood by those skilled in the art, this type of notation means that the phosphor can include any or all of those specified ions as dopants in the formulation.

Phosphor material can be provided with silicone material for color balancing. As described above, high performance blue LED devices are used as light source of the LED package. For example, a combination of yellow color from the phosphor material and the blue color from the LED provides white light that is typically used for general lighting. In various embodiments, an amount of phosphor material is selected based on the color balance of the blue LED devices. Phosphor material can be mixed with silicone material to produce white light for the LED package.

In a preferred embodiment, the wavelength conversion material is within about three hundred microns of a thermal sink. The thermal sink comprises a surface region and has a thermal conductivity of greater than about 15 Watt/m-Kelvin, 100 Watt/m-Kelvin, 200 Watt/m-Kelvin, 300 Watt/m-Kelvin, and larger.

In one embodiment, the wavelength conversion material is characterized by an average particle-to-particle distance of about less than about 2 times the average particle size of the wavelength conversion material, is characterized by an average particle-to-particle distance of about less than about 3 times the average particle size of the wavelength conversion material, is characterized by an average particle-to-particle distance of about less than about 5 times the average particle size of the wavelength conversion material, or other dimensions. In a more preferred embodiment, the wavelength selective surface is provided. In a preferred embodiment, the wavelength selective surface is a transparent material such as distributed Bragg Reflector (DBR) stack, a diffraction grating, a particle layer tuned to scatter selective wavelengths, a photonic crystal structure, a nanoparticle layer tuned for plasmon resonance enhancement at certain wavelengths, a dichroic filter, but can be others.

The above has been generally described in terms of entities that may be phosphor materials or phosphor-like materials, but it would be recognized that other “energy-converting luminescent materials,” which may include phosphors, semiconductors, semiconductor nanoparticles (“quantum dots”), organic luminescent materials, and the like, and combinations of them, and also be used. The energy converting luminescent materials generally are a wavelength converting material and/or materials.

In one embodiment, a cover member is provided over substrate, as shown on the partially processed device 303. The cover member is substantially transparent to allow light from LED devices to pass through. For example, various types of material may be used for the cover member, such as polymer material, glass material, and others. In a specific embodiment, the cover member is color to provide color balance. In one embodiment, color temperature of the LED devices is measured. Based on this color temperature, a specific color and/or color pattern is selected for the cover member so that the color balance light emitted from the LED devices through the cover member is essentially white, which is suitable for general lighting.

The partially processed device 303 as shown includes nine partially processed LED package in a 3×3 array. It is to be understood that the 3×3 array is only used for illustration. For example, for LED package with 6.5×6.5 mm dimension, an 8″ processed wafer could yield 690 LED package. For the LED package to be later used, the LED package is separated. Depending on the specific manufacturing processes used, the LED package may be separated from one another using scribing, cutting, and/or other processes.

As illustrated in FIG. 3, the LED device 304 as shown is a portion of the processed device 303. The LED device 304 includes, among other things, substrate, reflective layer, isolation layer, conductive pattern and/or circuits, LED devices electrically coupled to one another, silicone dam or casing, encapsulating material, and a cover member. As illustrated, the corners of the silicone dam and the cover member are partially cut off to provide for packaging.

FIG. 4 is diagram illustrating an LED package according to an embodiment of the present invention. An LED package 400, from a top view as shown in FIG. 4, includes an array of 36 LED devices connected in series and arranged in a 6×6 array. A 4.2×4.2 mm cavity area is provided for the LED devices, and the distance between two adjacent LED devices is about 0.6 mm. In an exemplary arrangement, the LED package is powered by an AC source with an rms voltage of approximately 110V. A specification for the exemplary LED package is provided below:

| Current/LEDs (Ave.) | 0.120 | A |
|---|---|---|
| Current Density (Ave.) | 200 | A/cm2 |
| Forward Voltage (Ave.) | 3.3-*3.8 | V |
| Power to LEDs (Ave.) | 14.7 | W |
| EQE | 55% | |
| Violet Power | 7.5 | W |
| White Power | 2.5 | W |
| Lumens/Wᵥᵢₒₗₑₜ | 141 | |
| Light Output | 1060 | Lumens |

The LED package with the specification is suitable for general lighting. As described below, the LED package is powered by 110 VAC power source. The lack of driver circuits, among other things, reduces the manufacturing cost of the LED package. Depending on the operation condition and requirements, other like arrangements (e.g., LED arrays for 220 VAC power source, or 12, 24, 36 VDC power source, etc.) are possible.

In other embodiments, the LED package can include other types of electronic devices such as an integrated circuit, a sensor, a micro-machined electronic mechanical system, or any combination of these, and the like. In addition, the silicon carrier substrate may contain embedded circuitry. In one embodiment, the LED package includes or is coupled to circuits that include logic devices, sensors, memory, or processing devices.

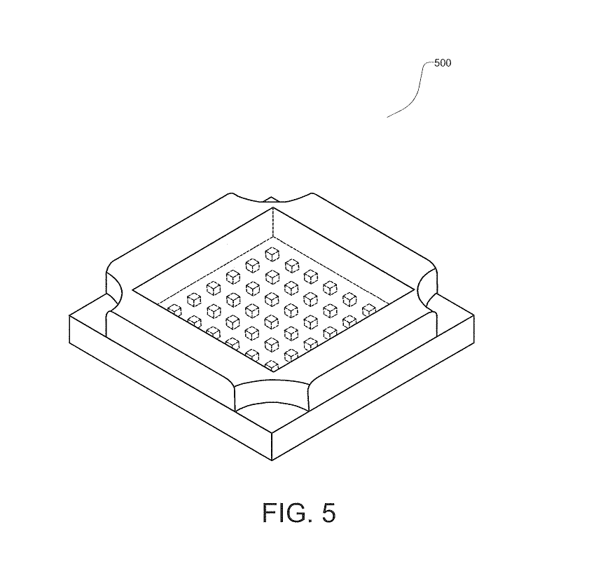

FIG. 5 is a diagram illustrating a 3D view of an LED package according to an embodiment of the present invention. The LED package as shown in FIG. 5 is configured to provide over 1000 lumens of light. As described above, no electrical vias are required to provide a connection to the bottom surface, thereby reducing the manufacturing costs of the LED package compared to other techniques. The LED package is manufactured in foundry compatible processes similar to that used in manufacturing silicon chips. In various embodiments as will be described below, semiconductor packaging techniques compatible with existing technology and equipment are used in packaging the LED package. For example, the LED package may be formed as a surface-mount device (“SMD”), or alternatively, onto a lead-frame which can be secured using screw, spade base, and other means.

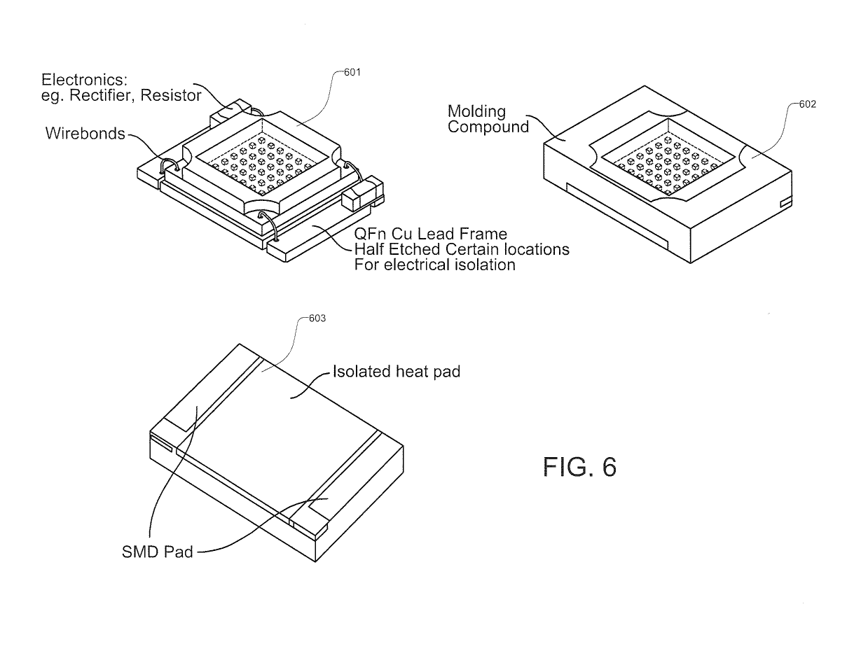

FIG. 6 is a diagram illustrating mounting of LED package according to embodiments of the present invention. As shown on device 601, an LED package is mounted on a lead frame made using Quad Flat No leads (QFN) copper lead frame and/or types of lead frame. As shown in FIG. 6, certain locations of the lead frame are half-etched to provide electrical isolation. The LED package is attached to the lead frame. Electrical components such as rectifiers and resistor are optionally provided on the lead frame and electrically coupled to the LED package to provide power to the LED package. The LED package is connected to electrical components and/or other electronics using wire bonds or other means for electrical connection.

As shown on device 602, a molding compound is used to seal various electrical components on the lead frame. In addition to provide electrical insulation, the molding compound also provides protection for both the LED package and the electrical components. The back of the lead frame, as shown on device 603, includes SMD pad interface for connecting to other electrical devices. The lead frame can also include isolated heat pad for dissipating heat generated by the LED devices. The isolated heat pad provides electrical isolation and heat conductivity to allow heat for the LED package to dissipate.

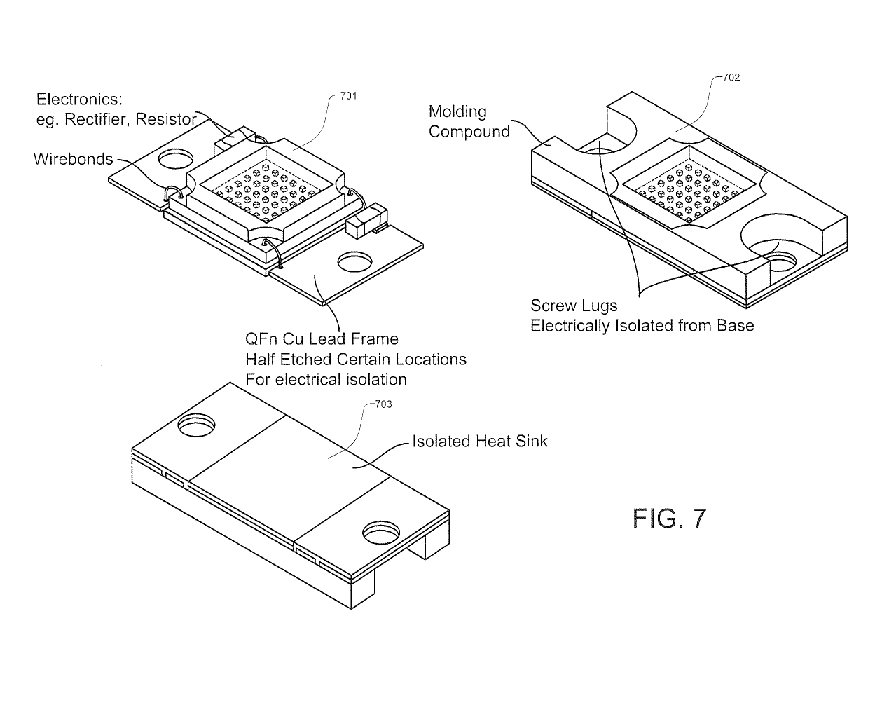

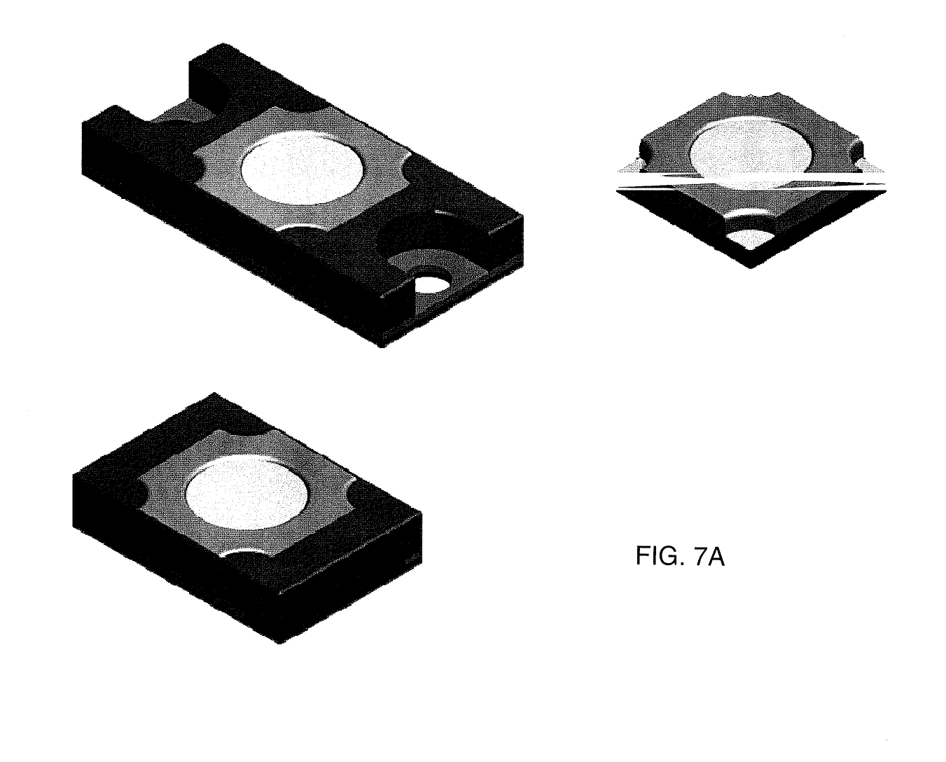

FIG. 7 is a diagram illustrating alternative mounting of LED package according to embodiments of the present invention. As shown on device 701, an LED package is mounted on a lead frame made using Quad Flat No leads (QFN) copper lead frame and/or types of lead frame. Certain locations of the lead frame are half-etched to provide electrical isolation. The LED package is attached to the lead frame. Electrical components such as rectifiers and resistor are provided on the lead frame and electrically coupled to the LED package to provide power to the LED package. The LED package is connected to electrical components and/or other electronics using wire bonds. In contrast to the device 601 shown in FIG. 6, the device 701 includes two openings, which are used for accommodating screws.

As shown on device 702, a molding compound is used to seal various electrical components on the lead frame. In addition to provide electrical insulation, the molding compound also provides protection for both the LED package and the electrical components. The device 702 includes two openings that are electrically isolated from the base of based of the LED package. The openings can be used for accommodating screw lugs and/or other types mounting means. The lead frame can also include isolated heat sink for dissipating heat generated by the LED devices. The screw lugs provide a means to electrically connect to the package. The screw lugs also provide means to mechanically press the heak sink region of the lead frame on to a heat dissipating surface such as a lead frame.

It is to be appreciated that the devices shown in FIGS. 6 and 7 are some of the ways for electrical, mechanical, and/or thermal interfaces to the LED packages. According to various embodiments of the present invention, other mounting mechanisms are provided, such as snap-on mounting, screwing, soldering, and others.

Device 701 as shown in FIG. 7 does not have to be in square or rectangular shape. FIG. 7A is a diagram illustrating an alternative mounting of circular LED package according to embodiments of the present invention. As shown in FIG. 7A, LED devices are arranged within a circular area. Depending on the application, LED devices can be arranged with other shapes of areas.

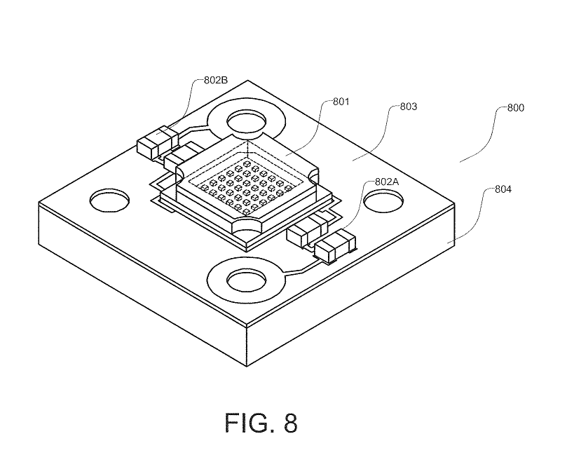

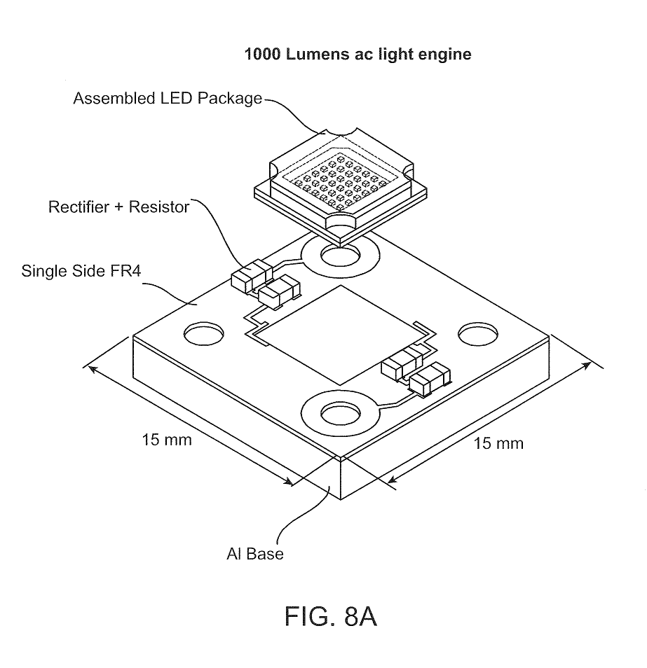

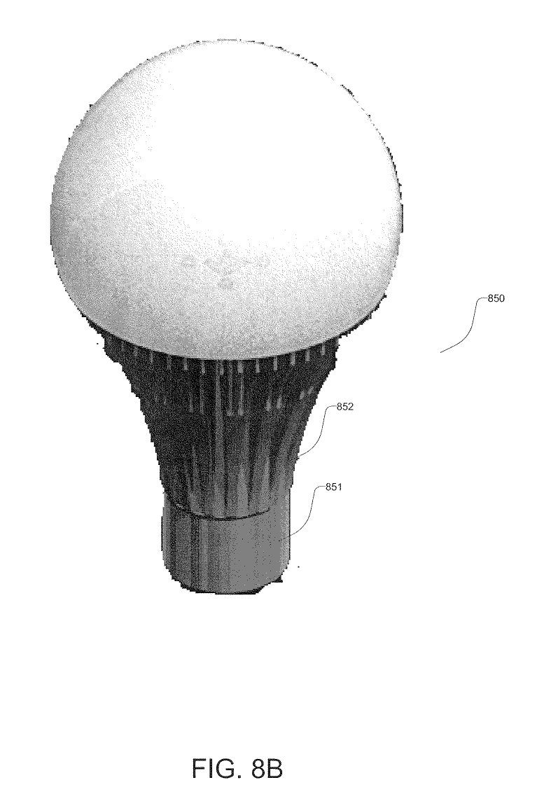

FIG. 8 is a diagram illustrating an AC powered LED light configured to provide over 1,000 lumens of light from a 110V AC power source. The PCB board 803 is mounted on a base 804. The base 804 helps dissipate heat generated by the LED package 801. The PCB has a hole that allowing a direct thermal contact between the LED package 801 and the base 84. An LED package 801 is electrically connected PCB 803 board. Electronics 802A and 802B are provided on the PCB board and connected to the LED package 801. Electronics 802A and 802B may include rectifiers, capacitors, and resistors for forming a power conditioning circuit.

FIG. 8A is a diagram of an exploded view of an AC powered LED light assembly according to an embodiment of the present invention. As shown an assembled LED package is mounted on to a PCB (by an SMT process, soldering or thermal adhesive).

It is to be appreciated that LED light according to the present invention can be implemented for various types of applications. FIG. 8B is a diagram illustrating an LED light system according to an embodiment of the present invention. An LED light (e.g., the LED light 800) is a part of the LED light system 850. The LED light system 850 includes a base 852 that also functions as a heat sink. The base member 851 is connected to the heat sink. The base member 851 is compatible with convention light bulb socket and is used to provide an electrical interface for the LED package in the LED light system 850.

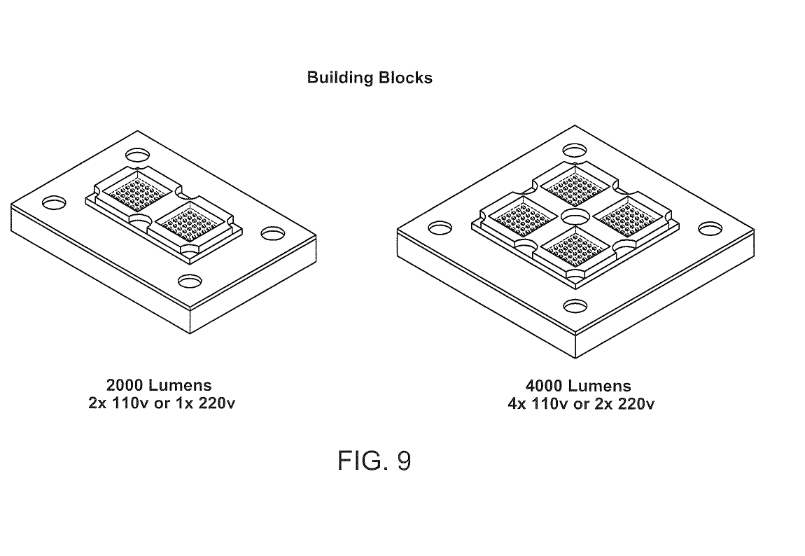

FIG. 9 is a diagram illustrating arrangements for LED packages. As shown on the left, two LED packages, each generating about 1000 lumens of light, are mounted together. The two LED packages can be powered by two 110V power sources or one 220V power source. As shown on the right, four LED packages, each generating about 1000 lumens of light, are arranged in a 4×4 array. The four LED packages can be powered by four 110V power sources or two 220V power sources. It to be appreciated that embodiments of the present invention provide the flexibility to allow different arrangements of LED packages that suit different output requirements.

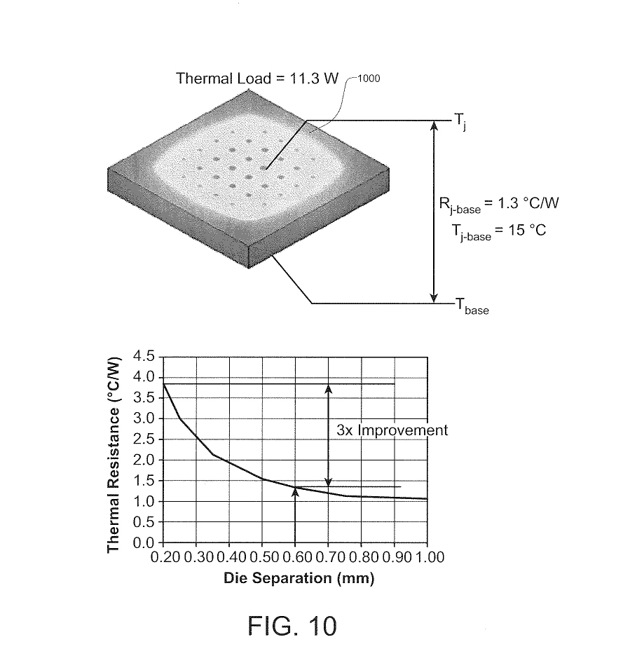

FIG. 10 is a diagram illustrating heat dissipation of LED packages of a structure according to an embodiment of the present invention. An LED package 1000 includes an array of LED devices that are electrically coupled to one another. When LED devices are powered and emitting light, the LED devices also generate heat. In particular, the hottest parts of the LED package are the LED devices when emitting light. The LED devices also heat the substrate and the base of the LED package, both of which help LED devices dissipating heat energy.

The LED package design according to the embodiments of the invention is better at dissipating thermal energy than conventional LED lights. More specifically, because LED devices, each having small active area, and are separated from one another, the LED package 1000 as shown has space for heat dissipation. In various embodiments, the base of the LED package 1000 is coupled to a heat sink. As shown in FIG. 10, that LED package has a thermal resistance of 1.3 C/W. This compares to a conventional a single large die LED arrange with 3× higher thermal conductivity.

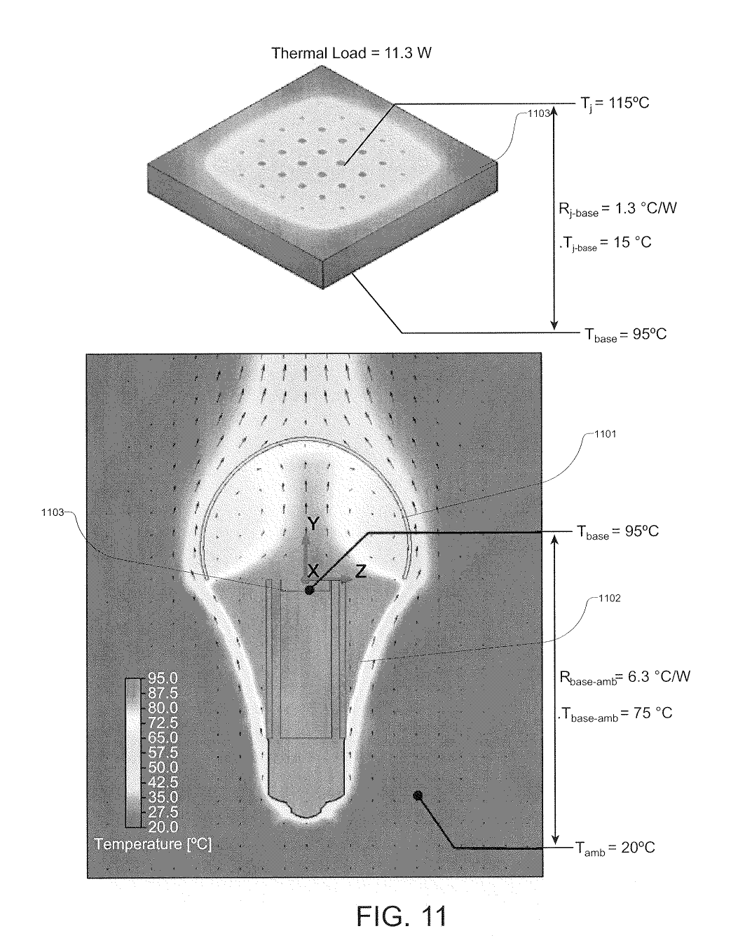

FIG. 11 is a diagram illustrating heat dissipation of an exemplary LED package attached to a heat sink for a retrofit lamp according to an embodiment of the present invention. An LED package 1103, similar to the LED package 1000, includes an array of LED devices that are electrically coupled to one another. When LED devices are powered and emitting light, the LED devices also generate heat. For example, during operation, the LED devices heat to a temperature of about 115 degrees C.

Thermally coupled to the LED devices, the base of the LED package has an operating temperature of about 95 degrees Celsius. As shown in FIG. 11, the LED package 103 is thermally coupled to a housing 1102, which includes a heat sink for dissipating heat. The heat sink of the housing 1102 is thermally coupled to the LED package 1103 and dissipates heat from its surface area, which is much bigger than the surface area of the LED itself. As shown in FIG. 11, the housing 1102 has a temperature of about 75 degrees Celsius when the LED devices are operating. The housing 1102 includes a substantially transparent cover 1101 which allows a portion of heat generated by the LED devices to dissipate from its surface. LED modules according to embodiments of the present invention provide improved heat dissipation. While both reliability and usability of conventional LED light sources are often limited by high temperature, the LED arrays according to the present invention are less prone to heat problems because heat energy is distributed among LED devices of the LED arrays.

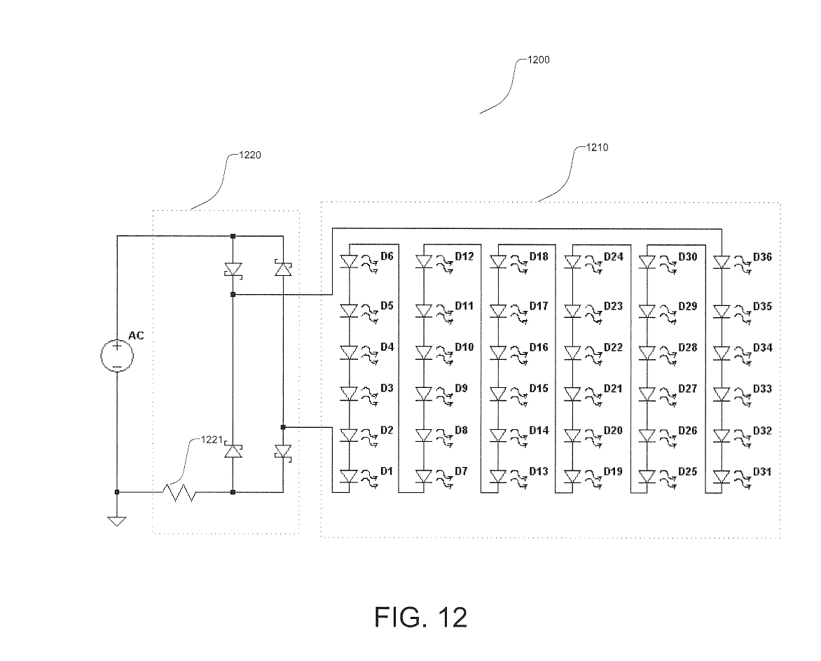

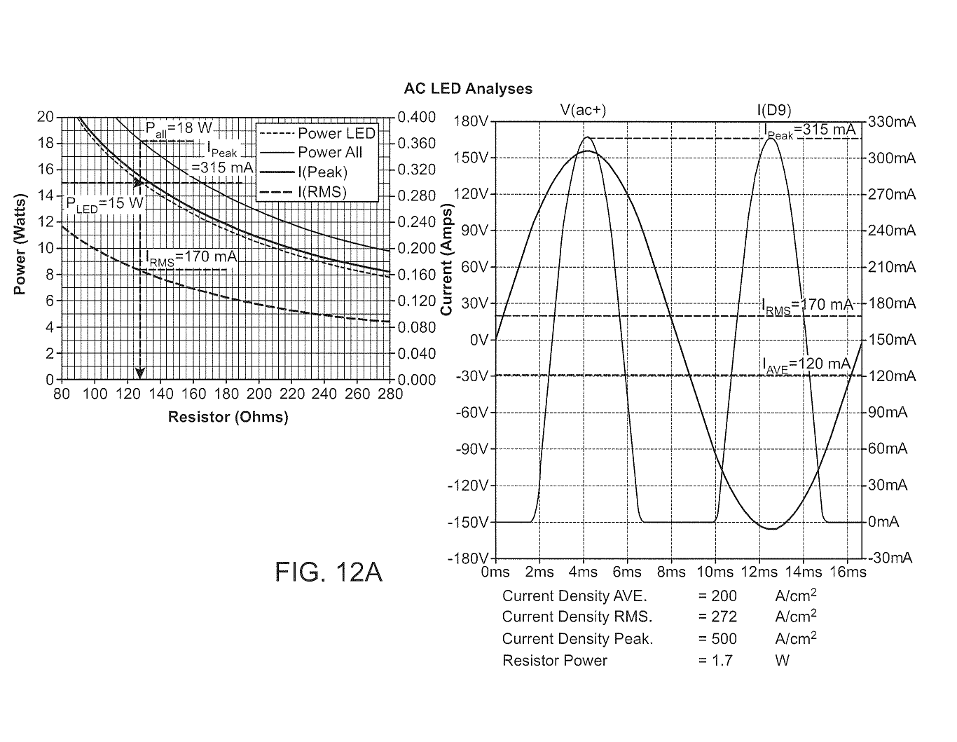

FIG. 12 is a diagram of a circuit diagram illustrating an LED array according to an embodiment of the present invention. As shown in FIG. 12, a circuit 1200 includes an LED section 1210 and a rectifier section 1220. The LED section 1210 includes 36 LED devices connected in series.

In one embodiment, LED devices of the same type, e.g. high performance blue LED devices, are connected in the LED section 1210 and powered by a 110V AC source. The rectifier section 1220 as shown in FIG. 12 is provided to rectify AC power for the LED section 1210. Rectifier section 1220 is used, instead of driver module typically need for conventional LED lights. Among other features, the rectifier section 1220 is implemented using simple rectifier circuitry including diodes and resistors, which is relatively inexpensive to manufacture and implement. For example, the resistor 1221 as shown has about 130 ohms of resistances and is used to match power requirement of the LED section 1210. Other electrical components may be electrically coupled to power AC power source. In certain embodiments, capacitors are provided to smooth the waveform generated by the rectifier section 1220.

It is to be appreciated that the LED devices are not powered by a conventional driver, which is usually required in conventional design of LED light. Instead using driver circuitry, the present invention enables use of rectifier circuits for powering LED devices. Rectifier circuits, consisting typically of diodes and resistors, are typically less expensive to implement compared to conventional driver circuits. Capacitors may also be included to condition the input voltage waveform to improve power factor or reduce “flicker” of the light emission during operation. As an example, the number of LED devices is selected to match the power source (e.g., 110V AC power source matched by 36 LED devices). Connected in series, the array of LED devices is able to utilize a high level of current density of as listed below:

| | | |
|---|---|---|
| Current Density AVE. | 200 | A/cm2 |
| Current Density RMS. | 272 | A/cm2 |
| Current Density Peak. | 500 | A/cm2 |
| Resistor Power | 1.7 | W |

FIG. 12A is a diagram illustrating operation of an LED array according to an embodiment of the present invention. As shown in FIG. 12A, the LED array illustrated in FIG. 12 and described above is able to accommodate a high level of current density, thereby operating efficiently. At the 110V AC level with a high level of currently density, the LED devices according to the present invention are able to output a high level of lumens without generating a high level of heat. In various embodiments of the present invention, LED arrays are designed to accommodate 220V AC, 12V DC, 24V DC, 36V DC, and other power sources. Depending on the application, different types of rectifier circuits can be used for accommodating these types of power sources.

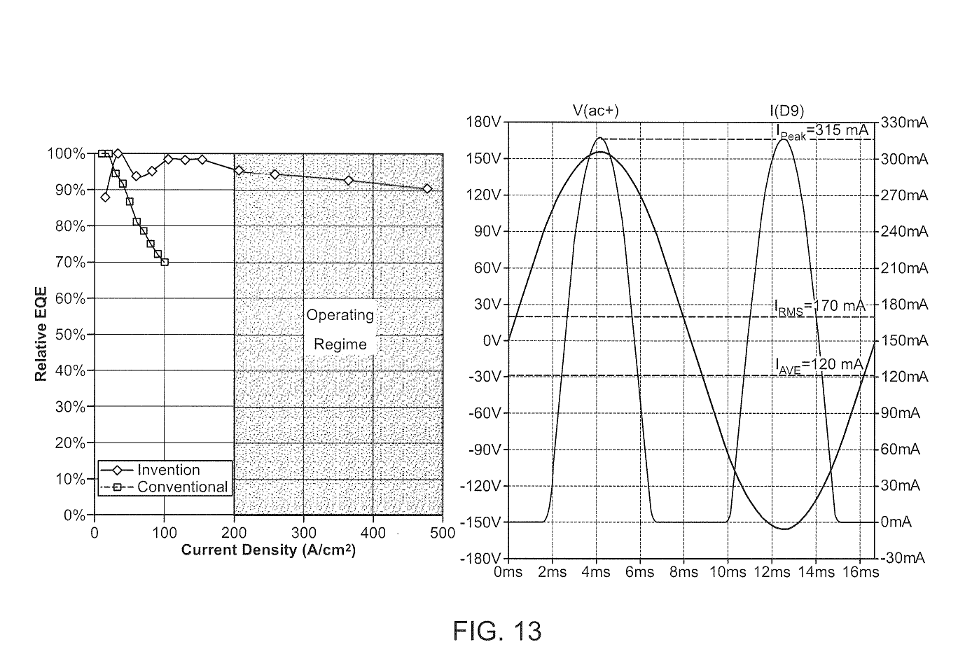

FIG. 13 is a diagram illustrating performance of our LED apparatus. In the graph on the left, relative external quantum efficiency (EQE) of LED arrays stays high at high current density. In addition, the LED arrays are able to operate at high current density. In comparison, relative EQE for conventional LED light typically drops quickly as current density increases.

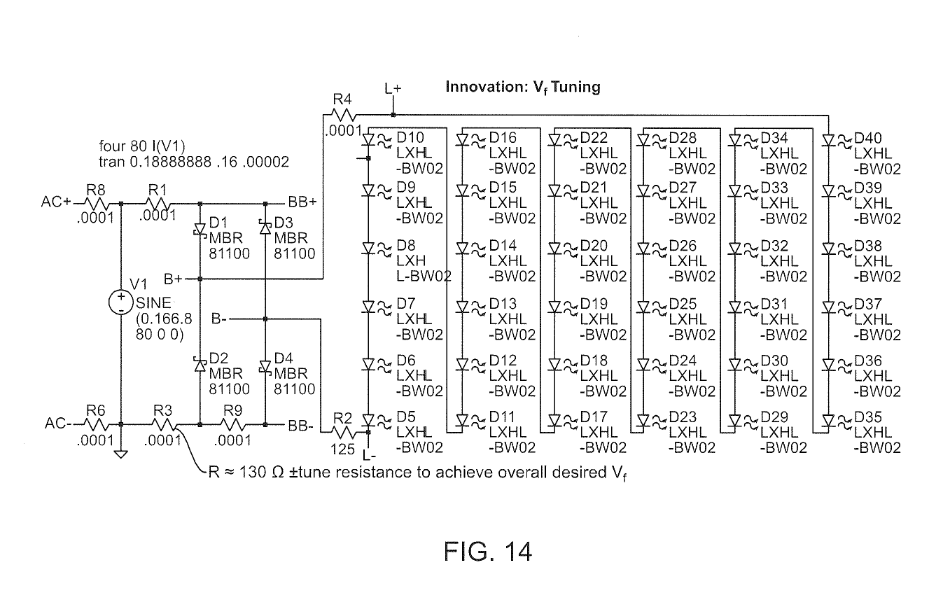

FIG. 14 is a circuit diagram illustrating an LED array with resistor tuning. As shown in FIG. 14, resistor R3 has a resistance of about 130 ohms which can be tuned to obtain a desirable forward current. Tuning of the resistor R3 allows for matching of LED V_{f} and resistance, and offers a trade-off between light output level and overall luminous efficacy.

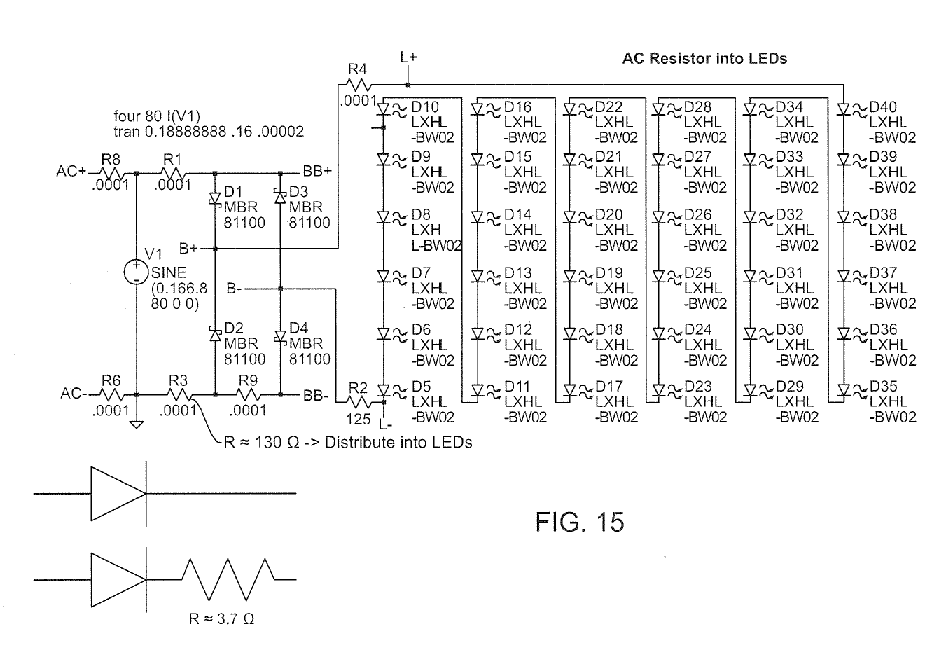

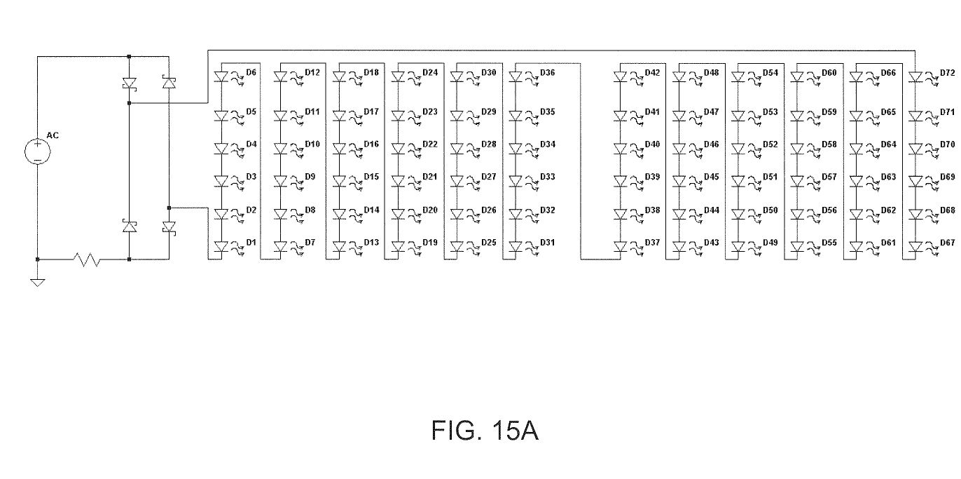

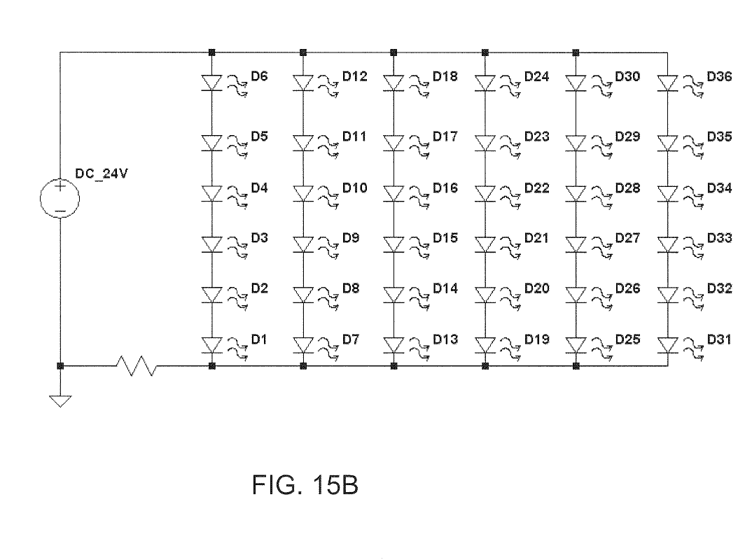

FIG. 15 is a circuit diagram illustrating an LED array with AC resistor according to an embodiment of the present invention. Resistor R3 help make LED resistive from bulk resistivity. Resistor R3 has a resistance of about 130 ohms. Distributed among the LED devices, the resistance for LED devices is about 3.7 ohm/LED (e.g., 130 ohms distributed over 36 LED devices). For example, the distributed V_{f} per LED is about 0.44V.

FIG. 15A is a circuit diagram illustrating an LED array configured to use a 220V AC power source. As shown, 72 LED devices are provided to match the voltage of the 220V AC power source, and a simple rectifier circuit provided between the AC power source and the LED devices.

FIG. 15B is a circuit diagram illustrating an LED array configured to using 24V DC power source according to an embodiment of the present invention. The LED devices are grouped into strings of six LED devices connected in series, and each string of LED devices is connected to one another in parallel. Since a DC power source is used, the LED devices are connected to the power source directly without a rectifier circuit. FIGS. 15A and 15B are only specific illustrations of an arbitrary number of possible configuration of LEDs in series and parallel configurations. Other configuration include but are not limited to: 1×36, 2×18, 3×12, 4×9, 6×6, etc.

It is to be appreciated that the LED packages illustrated in FIGS. 3-5 can output light in desirable color in various ways according to various embodiments of the present invention. Depending on the application, color balance can be achieved by modifying color generated by LED devices using phosphor material. Depending on the application, different schemes of color modification may be used, which is described in U.S. patent application “Reflection Mode Package for Optical Devices Using Gallium and Nitrogen Bearing Materials” (Attorney Docket No. 027364-009900US filed concurrently herewith), which is incorporated by reference herein for all purposes. In one embodiment, the phosphor material may be mixed with encapsulating material (e.g., silicone material) that seals LED devices into the LED package, and subsequently dispensing phosphor color pixels over LED devices.

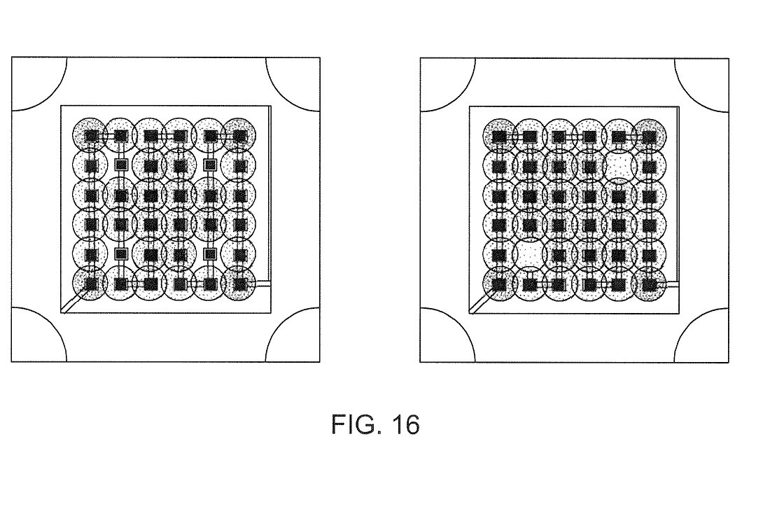

FIG. 16 is a diagram illustrating color tuning for LED devices. The LED package on the left includes blue color at its corners, green color at its edges, and red color at center. Together, these color pixels modify the color of light emitted by the LED devices. The color pixels are used to modify the light from LED devices to appear white, which is suitable for general lighting. In one embodiment, “blank” pixels are used for later color tuning and the color of the light from LED devices is measured.

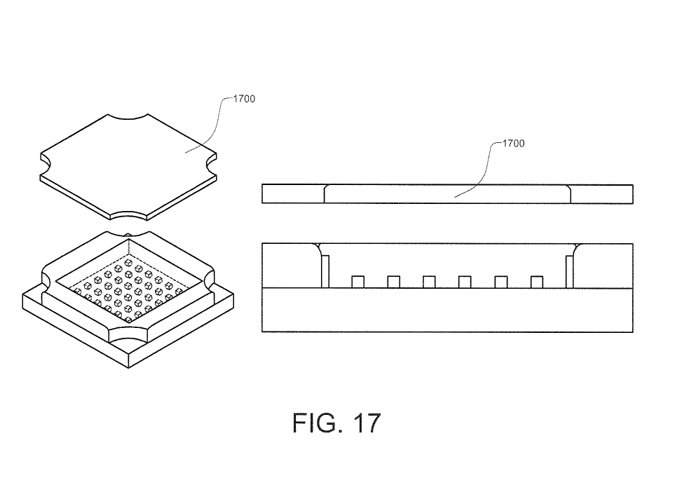

In various embodiments, color balance adjustment is accomplished by using pure color pixels, mixing phosphor material, and/or using blanket of phosphor over LED devices. Color balance tuning can be achieved by providing a color pattern on cover member of the LED package. FIG. 17 is a diagram illustrating color tuning using color filter for LED devices.

The cover member 1700 is used for providing color tuning. For example, the cover member 1700 is made of glass material and functions as a 405 nm reflection dichroic lens. The cover member is used as a reflection filter that filters out light with a wavelength of about 405 nm. Hermetic sealing technique may be used to couple the cover member 1700 to LED package. Color tuning using cover member can also be achieved through light absorption and/or light reflection.

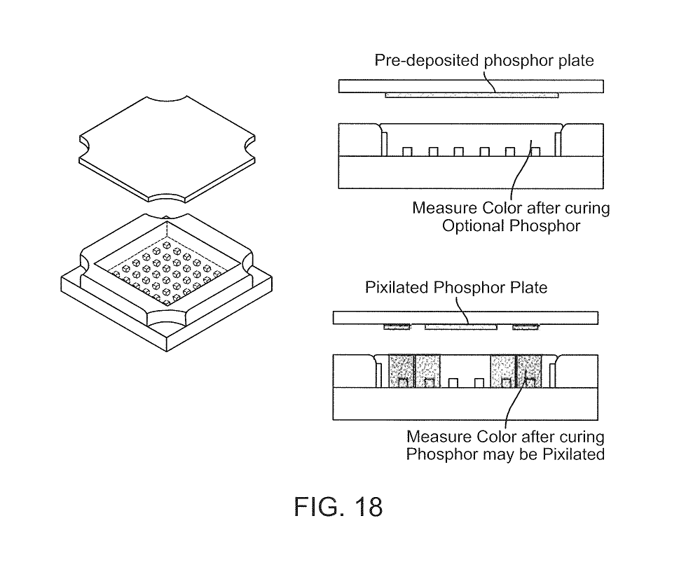

FIG. 18 is a diagram illustrating color tuning using a luminescent plate for LED devices. In one embodiment, a pre-deposited phosphor plate is attached to the cover member. After curing phosphor material encapsulating the LED devices, the color of the LED package can be measured. Based on the measured color, color for the phosphor plate can be determined and used to balance the color of the LED devices.

In an alternative embodiment, pixilated phosphor plates are attached to the cover. The pixilated phosphor plates include color patterns as shown in FIG. 18. Depending on the application, color patterns of the phosphor plate may be pre-selected or based on the measured color balance of the LED devices. In an alternative embodiment, the absorption plate, which is attached to the cover member, is used to perform color correction. For example, the absorption plate comprises color absorption material.

In the preferred embodiment, the pixilated phosphor structure would be employed for the present reflection mode device. To increase interaction with LED emitted light, a reflector covering the top of the package, redirecting LED light downward toward the phosphor layer is employed. Preferably, the pixilated structure includes one or more or all of the advantages of the previous embodiments, as well as adding reduced phosphor interaction and areal color control.

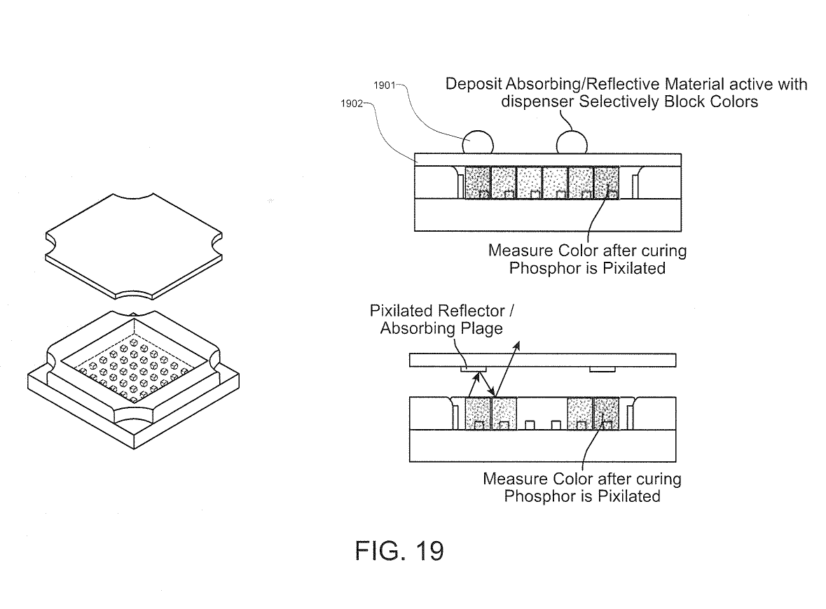

FIG. 19 is a diagram illustrating color tuning using absorbing and/or reflective material for LED devices. In one embodiment, pre-deposited phosphor plate is attached to the cover member. As shown in FIG. 19, absorbing and/or reflective material 1901 is deposited on cover member 1902. The absorbing and/or reflective material 1901 can be plastic, ink, die, glue, epoxy, and others. In other embodiments, the phosphor particles are embedded in a reflective matrix on the substrate by deposition. In one specific embodiment, the reflective matrix comprises silver or other suitable material, which may be ductile. In one specific embodiment, the deposition process comprises electroless deposition and the substrate is treated with an activating solution or slurry prior to deposition of the phosphor particles.

The activating solution or slurry preferably comprises at least one of SnCl₂,SnCl₄, Sn⁺², Sn⁺⁴, colloidal Sn (tin), Pd (palladium), Pt (platinum), or Ag (silver). The phosphor-covered substrate is placed in an electroless plating bath with a plating solution that includes at least one of silver ions, nitrate ions, cyanide ions, tartrate ions, ammonia, alkali metal ions, carbonate ions, and hydroxide ions. A reducing agent such as dimethylamine borane (DMAB), potassium boron hydride, formaldehyde, hypophosphate, hydrazine, thiosulfate, sulfite, a sugar, or a polyhydric alcohol. may be added to the solution

The color and amount of absorbing and/or reflective material 1901 dispensed on the cover member 1902 are based on a measured color balance of the LED devices. Alternatively, as explained above, one or more colored pixilated reflector plates are attached to the cover member to adjust color balance of the LED devices. Materials such as aluminum, gold, platinum, chromium, and/or others are deposited on the pixilated reflector plates to provide color balance. In a preferred embodiment, reflector plate reflects blue light to make light closer to green and/or red, or reflects green light to make light looks closer to read red.

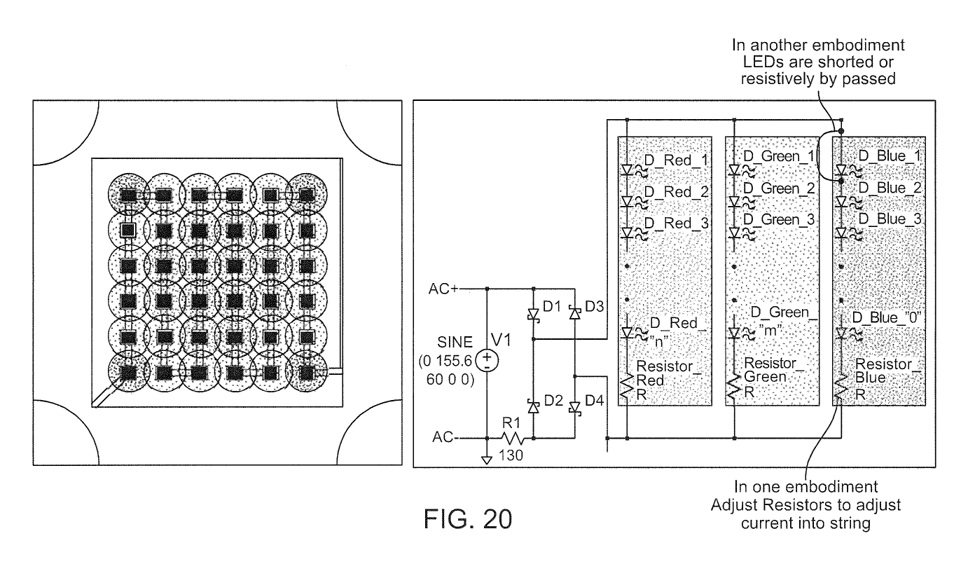

FIG. 20 is a diagram illustrating color tuning using LED devices with different colors. As shown in FIG. 20, three strings of LED devices are connected in parallel. Each string of LED devices is associated with a specific color: red, green, and blue. By mixing red, green, and blue light, white light can be generated. The color of each string of LED devices can be a result of color the LED devices themselves and/or color filtering of LED devices. It is to be appreciated in addition primal-color (e.g., RGB color) LED devices, other colors may be used for LED devices.

As shown in FIG. 20, each string of LED devices includes a number of LED devices of the same color. According to various embodiments, color balance can be achieved by adjusting the amount of current delivered to the LED strings. For example, each string of LED devices is connected to a resistor. By adjusting the resistors, the amount of current delivered to a string of LED devices can be adjusted, thereby adjusting the brightness of light in a particular color. In an alternative embodiment, color balance may be adjusting by adjusting the number of LED devices in an LED string used for light generation. For example, to reduce the amount of blue light, one or more LED devices in the blue string can be shorted or bypassed.

While the above is a full description of the specific embodiments, various modifications, alternative constructions and equivalents may be used. As an example, the packaged device can include any combination of elements described above, as well as outside of the present specification. Additionally, the above has been generally described in terms of one or more entities that may be one or more phosphor materials or phosphor like materials, but it would be recognized that other “energy-converting luminescent materials,” which may include one or more phosphors, semiconductors, semiconductor nanoparticles (“quantum dots”), organic luminescent materials, and the like, and combinations of them, can also be used.

The energy converting luminescent materials generally can be wavelength converting material and/or materials or thicknesses of them. Furthermore, the above has been generally described in electromagnetic radiation that directly emits and interacts with the wavelength conversion materials, but it would be recognized that the electromagnetic radiation can be reflected and then interact with the wavelength conversion materials or a combination of reflection and direct incident radiation. In other embodiments, the present specification describes one or more specific gallium and nitrogen containing surface orientations, but it would be recognized that any one of a plurality of family of plane orientations can be used. Therefore, the above description and illustrations should not be taken as limiting the scope of the present invention which is defined by the appended claims.

What is claimed is:

1. A method of manufacturing LED devices using substrate scale processing, the method comprising:
providing a substrate member having a surface region;
forming a reflective surface on the surface region, the reflective surface being characterized by a reflectivity of at least 85%;
forming an array of regions spatially disposed over the reflective surface; and
providing a plurality of LED devices, individual ones of which are disposed on corresponding ones of the array of regions.

2. The method of claim 1 wherein the substrate member comprises a silicon substrate.

3. The method of claim 1 wherein the reflective surface comprises a silver or aluminum material.

4. The method of claim 1 wherein the array of regions comprises an N by M array, where N is an integer of at least 2 and M is an integer of at least 1.

5. The method of claim 1 wherein each LED device comprises gallium and nitrogen formed from bulk substrate material.

6. The method of claim 1 further comprising encapsulating each of the plurality of LED devices with an encapsulating material comprising a wavelength conversion material.

7. The method of claim 6 wherein the wavelength conversion material comprises at least one of a phosphor, a semiconductor, and a luminescent material.

8. The method of claim 1 wherein the step of forming a reflective surface comprises depositing a silver material or aluminum over the surface region.

9. The method of claim 1 wherein the step of forming a reflective surface comprises:
forming a reflective metal material over the surface region;
forming at least one dielectric material over the metal material; and
forming a plurality of electrically conductive array regions over dielectric material

10. The method of claim 1 wherein the step of forming a reflective surface comprises:
forming a dielectric material over the substrate surface region; and
forming a plurality of electrically conductive reflective array regions over the dielectric material.

11. The method of claim 1 wherein the step of forming a reflective surface comprises:
forming a dielectric material over the substrate surface region;
forming a plurality of electrically conductive array regions over the dielectric material; and
forming a electrically insulating but optically reflective layer on top one portion of dielectric material or electrically conductive array region.

12. A light emitting diode apparatus comprising:
a substrate member having a surface region;
a reflective layer overlaying the surface region, the reflective layer having a first reflectivity level;
an isolation layer overlying the reflective layer;
an array of regions disposed on the isolation layer;
a plurality of LED devices disposed on corresponding ones of the array regions.

13. The apparatus of claim 12 wherein each of the array of regions includes a conductive pattern.

14. The apparatus of claim 12 wherein the reflective layer and the isolation layer have a combined reflectivity of greater than 93%.

15. The apparatus of claim 12 wherein the substrate has a conductivity of greater than 40 W/(m-K).

16. The apparatus of claim 12 wherein the isolation layer comprises SiN material.

17. An LED apparatus comprising:
a substrate having a surface region;
a reflective layer overlying the surface region, the reflective layer being characterized by a first reflectivity level;
an isolation layer over the reflective layer;
an array of conductive regions disposed on the isolation layer;
a plurality of LED devices, individual ones of which are positioned on each of the array regions; and
a cover member overly the plurality of LED devices.

18. The apparatus of claim 17 further comprising a rectifier circuit coupled to the array of conductive regions.

19. The apparatus of claim 18 further comprising a resistor electrically coupled to the rectifier circuit.

20. The apparatus of claim 17 wherein the plurality of LED devices include a first LED set and a second LED set, each of the LED sets including a plurality of LED devices connected in series, the first LED set and the second LED set being configured in parallel to each other.
